(19) United States
(12) Patent Application Publication
(10) Pub. No.: US 2022/0397533 A1
(43) Pub. Date: Dec. 15, 2022

(54) ALUMINUM THIN FILM MICROARRAY CHIP SUBSTRATES FOR BIOSENSING VIA SURFACE PLASMON RESONANCE SPECTROSCOPY AND IMAGING

(71) Applicant: The Regents of the University of California, Oakland, CA (US)

(72) Inventors: Quan Jason Cheng, Irvine, CA (US); Alexander Scott Lambert, San Gabriel, CA (US); Santino Nicholas Valiulis, Los Angeles, CA (US); Alexander Scott Malinick, Chino Hills, CA (US); Ichiro Tanabe, Osaka (JP); Bochao Li, Riverside, CA (US)

(21) Appl. No.: 17/805,971

(22) Filed: Jun. 8, 2022

Related U.S. Application Data
(60) Provisional application No. 63/209,276, filed on Jun. 10, 2021.

(51) Int. Cl. G01N 21/65; H01J 49/16; C23C 14/18; C23C 14/30; C23C 14/58

(52) U.S. Cl. CPC G01N 21/658; H01J 49/164; C23C 14/18; C23C 14/30; C23C 14/5853

(57) ABSTRACT

A thin aluminum film substrate and microarrays thereof including a substrate and a thin film of aluminum deposited on the substrate for surface plasmon resonance analysis. Methods of forming the thin aluminum film substrate and microarrays including providing a substrate, using electron-beam physical vapor deposition (EBPVD) to deposit a thin film of Al on a surface of the substrate. Also disclosed are methods of detecting an analyte, wherein a functionalized surface of the thin aluminum film includes a biomolecule and the methods include applying a sample including the analyte to the thin aluminum film substrate, and using surface plasmon resonance (SPR) spectroscopy to detect molecular interactions between the biomolecule and the analyte at a surface of the thin aluminum film substrate. In some examples, an unmodified Al film with an Al₂O₃ layer is effective in enriching phosphorylated peptides. In some examples, a coating of an ionic polymer is used to analyze charged-based interactions of biomolecules.

### STATEMENT REGARDING FEDERALLY SPONSORED R&D

This invention was made with government support under Grant Number CHE-143449 awarded by the National Science Foundation (NSF) and Grant Number R21AI140461 awarded by the National Institutes of Health (NIH). The government has certain rights in the invention.

### FIELD OF THE INVENTION

The invention relates to substrates, new optical effects and novel surface chemistry for plasmonic biosensing.

### REFERENCE TO SEQUENCE LISTING

A Sequence Listing submitted as an ASCII text file via EFS-Web is hereby incorporated by reference in accordance with 35 U.S.C. § 1.52(e). The name of the ASCII text file for the Sequence Listing is 55756164_1.TXT, the date of creation of the ASCII text file is Jun. 8, 2022, and the size of the ASCII text file is 1.34 KB.

### BACKGROUND

Surface plasmon resonance (SPR) spectroscopy is a well-established analytical technique for label-free quantification of molecular interactions at an interface (Homola, J.; Yee, S. S.; Gauglitz, G. Sens. Actuators, B 1999, 54 (1-2), 3-15). The method relies on detecting the minute changes in refractive index of a dielectric medium in contact with a nanometer-scale thin metal film (Homola, J. Chem. Rev. 2008, 108 (2), 462-493). The metal layer used has traditionally been gold due to its high plasmonic activity and inert chemical character. We have previously reported the development and use of ultrathin calcinated films on a gold surface for highly effective laser desorption/ionization of biomolecules (U.S. Pat. No. 9,671,409). Increasing attention, however, is being invested toward other metals such as chromium (Sadeghi, S. M.; Hatef, A.; Nejat, A.; Campbell, Q.; Meunier, M. J. Appl. Phys. 2014, 115 (13), 134315), copper (Zhou, M.; Tian, M.; Li, C. Bioconjugate Chem. 2016, 27 (5), 1188-1199), and aluminum (Gerard, D.; Gray, S. K. J. Phys. D: Appl. Phys. 2015, 48 (18), 184001) as plasmonic materials. Aluminum is particularly attractive as it has a high electron density (3 electrons per atom in its conduction band versus 1 electron for gold and silver) and a generally higher negative permittivity than silver or gold (Rakić, A. D. Appl. Opt. 1995, 34 (22), 4755-4767). This property leads to plasmonic resonance in a very large wavelength range, making aluminum plasmonically active from the ultraviolet to near-infrared regimes. Aluminum is also appealing for commercial applications due to high abundance, low-cost, and easy integration into manufacturing processes such as complementary metal oxide semiconductor (CMOS) (Knight, M. W.; King, N. S.; Liu, L. F.; Everitt, H. O.; Nordlander, P.; Halas, N. J. ACS Nano 2014, 8 (1), 834-840).

Commercial SPR substrates are limited to a single metal type, Au, which limits the range of functionalization chemistry to gold-thiol bonds and thus limits application types. Additionally, Au has a high amount of fouling behavior in biological samples, which in turn requires significant cost and engineering effort to overcome and further limits applications, especially in the medical field. While alternative metals such as Al, In or Ti have been discussed and theorized, they have not been seriously considered or implemented for practical applications in standard Kretschmann configuration in thin film form.

The search for improved plasmonic materials is wide-ranging, as the increasing miniaturization of technological applications requires more and more optic and photonic devices to utilize the nano-scale effects available from plasmonic absorption of photons (West, P. R.; Ishii, S.; Naik, G. V.; Emani, N. K.; Shalaev, V. M.; Boltasseva, A., Searching for better plasmonic materials. Laser Photon. Rev. 2010, 4 (6), 795-808). In the analytical sciences, the rapid growth of the bioanalytical and biopharmaceutical fields requires more analytical methods that operate on the nanoscale to probe the fine dynamics of cellular components such as proteins, lipids, and nucleic acids. For direct biosensing and more complex bioanalysis, a large component of plasmonic applications come in the form of SPR spectroscopy, which uses an attenuated total reflection (ATR) configuration to sensitivity detect mass or solution changes at a surface in real-time at a range of ˜200 nm (Tang, Y. J.; Zeng, X. Q.; Liang, J., Surface Plasmon Resonance: An Introduction to a Surface Spectroscopy Technique. JOURNAL OF CHEMICAL EDUCATION 2010, 87 (7), 742-746). SPR applications are typically dominated by Au films, but we have recently reported on the fundamental optical and biosensing properties of thin Al films in SPR configurations (Lambert, A. S.; Valiulis, S. N.; Malinick, A. S.; Tanabe, I.; Cheng, Q., Plasmonic Biosensing with Aluminum Thin Films under the Kretschmann Configuration. Analytical Chemistry 2020, 92 (13), 8654-8659). In particular, Al films were demonstrated to be of higher native sensitivity than Au in the SPR imaging mode that uses a fixed angle reflected intensity to widen the analyzable area to an entire array. Aluminum also has the practical advantages of high abundance, lower cost, and easier integration into a variety of manufacturing processes compared to Au and Ag (Knight, M. W.; King, N. S.; Liu, L. F.; Everitt, H. O.; Nordlander, P.; Halas, N. J., Aluminum for Plasmonics. ACS Nano 2014, 8 (1), 834-840).

Aside from SPR-based applications, thin aluminum films have significant potential towards high-sensitivity MALDI-MS-based analysis. Al foils and nanostructures as substrates have been investigated and reported as beneficial for matrix-assisted laser desorption ionization mass spectrometry (MALDI-MS) (Li, Y.; Liu, Y.; Tang, J.; Lin, H.; Yao, N.; Shen, X.; Deng, C.; Yang, P.; Zhang, X., Fe₃O₄@ Al₂O₃ magnetic core-shell microspheres for rapid and highly specific capture of phosphopeptides with mass spectrometry analysis. JOURNAL OF CHROMATOGRAPHY A 2007, 1172 (1), 57-71; Qiao, L. A.; Bi, H. Y.; Busnel, J. M.; Hojeij, M.; Mendez, M.; Liu, B. H.; Girault, H. H., Controlling the specific enrichment of multi-phosphorylated peptides on oxide materials: aluminium foil as a target plate for laser desorption ionization mass spectrometry. CHEMICAL SCIENCE 2010, 1 (3), 374-382; and Bondarenko, A.; Zhu, Y.; Qiao, L.; Salazar, F. C.; Pick, H.; Girault, H. H., Aluminium foil as a single-use substrate for MALDI-MS fingerprinting of different melanoma cell lines. ANALYST 2016, 141 (11), 3403-3410). In particular, the native aluminum oxide layer is selective for the charge density of phosphorylated peptides (Wolschin, F.; Wienkoop, S.; Weckwerth, W., Enrichment of phosphorylated proteins and peptides from complex mixtures using metal oxide/hydroxide affinity chromatography (MOAC). PROTEOMICS 2005, 5 (17), 4389-4397), so Al can serve as a means for their enrichment prior to quantification. Furthermore, an attractive plasmonic property of Al compared to Au and Ag is Al's ability to plasmonically absorb a broader spectrum of incident photon wavelengths. While Au's plasmonic absorption dramatically decreases at wavelengths lower than ˜500 nm, Al can absorb well into the UV range (Gerard, D.; Gray, S. K., Aluminium plasmonics. J. Phys. D-Appl. Phys. 2015, 48 (18), 14). This is highly relevant for MALDI-MS analysis due to the near-UV lasers typically used to ionize sample matrices for desorption. The effect of plasmonic Au on MALDI-ionization has been demonstrated recently (Shanta, P. V.; Li, B.; Stuart, D. D.; Cheng, Q., Plasmonic Gold Templates Enhancing Single Cell Lipidomic Analysis of Microorganisms. Analytical Chemistry 2020, 92 (9), 6213-6217; and Li, B.; Stuart, D. D.; Shanta, P. V.; Pike, C. D.; Cheng, Q., Probing Herbicide Toxicity to Algae (Selenastrum capricornutum) by Lipid Profiling with Machine Learning and Microchip/MALDI-TOF Mass Spectrometry. Chemical Research in Toxicology 2022, 35 (4), 606-615) so a similar effect could be used for plasmonic Al substrates. The coupling of SPR imaging and MALDI-MS analysis has also been demonstrated in previous work with thin Au films arrays. The higher sensitivity of plasmonic Al films in the imaging mode and the higher absorption of Al towards incident UV radiation make it a good overall candidate for coupled SPR-MALDI analysis.

### SUMMARY OF THE INVENTION

Some examples relate to a thin aluminum film substrate for surface plasmon resonance analysis including:
a substrate, and
a thin film of aluminum deposited on the substrate.

In some examples, the substrate includes a material selected from the group consisting of silicate glass, borosilicate glass, quartz, sapphire, polymerized polylactic acid, and polymerized poly(methyl methacrylate).

In some examples, the thin film of aluminum includes aluminum metal and an oxidized layer of Al₂O₃ on the aluminum metal.

In some examples, a ratio of the Al/Al₂O₃ is about 4:1.

In some examples, a thickness of the Al is between 10-200 nm and a thickness of the Al₂O₃ is about 1-20 nm.

In some examples, a thickness of the Al is about 12 nm and a thickness of the Al₂O₃ is about 3 nm.

In some examples, the thin metal film is attached to an attenuated total reflection (ATR) optical coupler.

In some examples, the layer of Al₂O₃ is functionalized to enable immobilization of a biomolecule.

In some examples, the layer of Al₂O₃ is functionalized by silanization, carboxylation or phosphonylation.

In some examples, the functionalized layer of Al₂O₃ is bound to biotin.

Other examples relate to a microarray with a plurality of wells including the thin aluminum film substrate according claim 1 deposited at the bottoms of the wells, wherein wells are surrounded by a layer of aluminum deposited on the substrate that is thicker compared to the layer of aluminum deposited at bottoms of the wells.

In some examples, the wells are 100-300 nm deep and 400-800 μm in diameter.

Other examples relate to a method of forming the thin aluminum film substrate for surface plasmon resonance analysis according to claim 1, the method including:
providing a substrate,
using electron-beam physical vapor deposition (EBPVD) to deposit a thin film of Al on a surface of the substrate.

In some examples, the method further includes allowing the thin film of aluminum to oxidize so that the thin aluminum film includes a layer of Al₂O₃.

Other examples relate to a method of forming the microarray according including:
providing a substrate,
applying a photoresist to the substrate,
applying well spots of photomask to the photoresist to define areas that will become wells in the microarray,
depositing aluminum by EBPVD onto the masked substrate, wherein a thin layer of aluminum is deposited onto areas not blocked by the photomask,
removing the well spots of photomask, and
depositing aluminum by EBPVD onto the microarray to build up walls around the wells and to coat the bottoms of the wells that are no longer masked.

Other examples relate to a method of detecting an analyte including:
providing the thin aluminum film substrate according to claim 1, wherein a functionalized surface of the thin aluminum film includes a biomolecule,
applying a sample including the analyte to the thin aluminum film substrate, and
using surface plasmon resonance (SPR) spectroscopy to detect molecular interactions between the biomolecule and the analyte at a surface of the thin aluminum film substrate.

In some examples, the method further includes allowing the thin film of aluminum to oxidize so that the thin aluminum film includes a layer of Al₂O₃.

In some examples, a sensor biomolecule is attached to a functionalized surface of the thin aluminum film is biotin and the analyte in the sample is conjugated to streptavidin.

In some examples, the sample including the analyte is a blood or serum sample, and wherein the Al/Al₂O₃ layer suppresses nonspecific binding from proteins and lipids in the blood or serum sample.

In some examples, the SPR spectroscopy includes SPR imaging.

Some examples relate to a method of enriching phosphorylated peptides on an aluminum array in SPR biosensing, SPR imaging or MALDI-MS analysis including using a thin aluminum film substrate which includes aluminum metal and an oxidized layer of Al₂O₃ on the aluminum metal.

In some examples, the thin aluminum film substrate further comprising a coating of an ionic polymer.

In some examples, the ionic polymer is selected from the group consisting of 1-Palmitoyl-2-oleoyl-glycero-3-phosphocholine (POPC), 1,2-dioleoyl-sn-glycero-3-ethylphosphocholine (EPC), and 1-palmitoyl-2-oleoyl-sn-glycero-3-phospho-(1′-rac-glycerol) (POPG).

Some examples relate to a method of analyzing charged-based interactions of biomolecules including using a thin aluminum film substrate coated with an ionic polymer.

### BRIEF DESCRIPTION OF THE DRAWINGS

FIG. 1. (a) Illustration of Kretschman configuration with the Al film. (b) Comparison of experimental angular spectrum of 12/3 Al/Al₂O₃ film in water at 650 nm to theoretical calculation from the Fresnel equations. (c) FDTD simulations of reflectivity of aluminum thin films with a 3 nm alumina overlayer in water.

FIG. 2. Experimental bulk refractive index testing. (a) Measured angular spectra of aluminum film with varying refractive indices from 1.33 to 1.37. (b) Shift in angular dip for gold and aluminum films. (c) Change in reflected intensity at a fixed angle and (d) across the Au linear range. (e) Simulated spectra for aluminum and gold superimposed onto each other and (f) a comparison of the reflectivities across the lower-angle side of the plasmonic dip.

FIG. 3. SPR sensorgrams of biosensing with Al thin films. (a) Streptavidin sensing on aluminum surface that had been incubated with biotin-BSA (gray) and just BSA (black). (b) Streptavidin sensing in undiluted human serum; inset: undiluted serum on the bare Al surface. The streptavidin concentration in the experiments is 500 μg/mL.

FIG. 4. SPR imaging with Al thin films. (a) Fabrication scheme of the microarray substrate. (b) Online image of an array with water over the wells. (c) Comparison of well brightness with incubation of increasing refractive index solutions. (d) Comparison of percent change in reflectivity using Al and Au films across full and (e) Au linear ranges.

FIG. 5. Layer configuration for Fresnel-based calculation (t=thickness).

FIG. 6. AFM image of deposited Al/Al₂O₃ film.

FIG. 7. Angular SPR spectra of on-line stability test of 12/3 nm Al/Al₂O₃ film with continuous 1×PBS buffer flow for 24 hr. Inset: SPR sensorgram of same experiment.

FIG. 8. SPR sensorgram of undiluted human serum incubated onto 50 nm Au film, followed by rinse.

FIG. 9. MALDI-MS spectra of casein peptides from digest on Al thin film with and without enrichment. (a) α-casein. (b) α-caasein, post-enrichment. (c) β-casein. (d) β-casein, post-enrichment. Lists of identified peptides are shown to the right of each spectrum, phosphorylated peptides in red and phosphorylated resides underlined.

FIG. 10. Binding of charged lipid vesicles to Al/Al₂O₃ surfaces with and without ionic polymer modification. (a) Surface diagram; (b), (d) and (f): SPR sensorgrams of binding of EPC, POPG, and POPC vesicles, respectively, to Al₂O₃, and PAH- and PAA-modified surfaces; (c), (e) and (g): Bar chart summaries of all experiments.

FIG. 11. (a) Chemical structures of ionic polymer compounds considered for SPR imaging; (b) SPR imaging reflectivity curves of polymer-modified Al microarrays.

FIG. 12. (a) Al SPR imaging microarray modified with ionic polymers. Solution flow was “bottom up”, so top blue row was auxiliary blank channel. (b) Comparison SPR imaging reflectivity changes in each channel from NaCl solutions of varying concentrations.

FIG. 13. (a) SPR imaging sensorgram example using averaged well intensities indicating regions of analysis. (b)-(e) Bar chart summaries of reflectivity shifts from incubations of CXCL biomarkers.

FIG. 14. Bar chart summaries of: (a) kinetic vs. (b) endpoint SPR imaging reflectivity shifts from incubations of CXCL biomarkers spiked in artificial urine matrix.

FIG. 15. Linear MALDI-MS spectra of 100 μg/mL of CXCL biomarkers on Al microarray. (a) CXCL8, (b) CXCL10.

FIG. 16. Linear MALDI-MS spectra of 20 μg/mL of CXCL biomarkers on Al microarrays with and without ionic polymer surface modification. (a) CXCL8; (b) CXCL10; (c) CXCL8: PLL; (d) CXCL10:PLL; (e) CXCL8:PAA; (f) CXCL10: PAA; (g) CXCL8: PSS; and (h) CXCL10:PSS.

FIG. 17. (a) Silanization surface chemistry. In this work, R═—CH2CH3 and R′=-PEG(2K)-Biotin. (b) SPR sensorgram of incubations of streptavidin and bovine serum albumin (BSA) on separate channels of a silane-functionalized Al chip.

FIG. 18. Comparison of MALDI-MS of POPC on: (a) Aluminum chip and (b) traditional stainless steel MALDI plate. The intensity of analyte signal (4 mg/ml POPC) from the Al chip is clearly higher than that from the traditional MALDI plate. (c) A calibration curve for the peak intensity of POPC comparing the Al-chip (orange) and traditional stainless steel MALDI plate (blue). POPC is used as standard to compare the sensitivity of Al-chip and traditional MALDI plate. The concentration gradients are 0.05, 0.1, 0.5, 1, 2, 4 mg/ml. The intensity of signal from Al-chip is higher than that from the traditional MALDI plate for all the concentrations that we used, and the signal is still detectable at 0.1 mg/ml which is barely observed from the traditional plate. It indicates that Al-chip has a higher sensitivity and lower limit of detection than traditional MALDI plate does.

### DETAILED DESCRIPTION

In this work, modifications and reactions at the aluminum surface are investigated in order to broaden the scope of applications for plasmonic aluminum thin films. Key to these applications are Al thin film microarrays that can be used interchangeably with SPR imaging and MALDI-MS. First, the coordination of Al₂O₃ with phosphate groups is used for enrichment of phosphorylated peptides on an aluminum array for MALDI-MS analysis. Second, physical surface modification via coatings of ionic polymers is employed to analyze charged-based interactions of biomolecules. The expansion of surface chemistry routes via its native oxide layer of Al₂O₃ would serve to broaden its implementation into conventional SPR experimental setups. The high sensitivity of Al in the imaging mode renders it a good candidate for array-based analysis to compare performances of different surface configurations. As a model system, two urinary chemokine biomarkers CXCL8 and CXCL10 were analyzed for their relative binding dynamics in both buffer and urine matrices. Finally, the direct chemical modification of the Al/Al₂O₃ surface for SPR biosensing was achieved with a silanization-based immobilization scheme of the sensing moiety for determination of bacterial protein streptavidin.

### Al Thin Film Substrates and Microarrays Fabricated Via Photolithographic and Evaporation Techniques.

BK-7 glass slides were cleaned using boiling piranha solution (3:1 H₂SO₄:30% H₂O₂) for 1 hr, followed by rinsing with ultrapure water and ethanol and drying with compressed nitrogen gas. For conventional SPR chips, 15 nm (5.0 Å/s) of aluminum was evaporated onto the slide via electron beam physical vapor deposition (EBPVD). All EBPVD was conducted at 5×10⁻⁶ Torr in a Class 1000 cleanroom facility. SPR imaging arrays were fabricated in accordance to previously described methods? with some modification. Cleaned glass slides were spin-coated with hexamethyldisilazane (HMDS) to promote adhesion, followed by AZ5214E, both at 4000 RPM for 45 s. A photoresist (also known simply as a resist) is a light-sensitive material used in photolithography to form a patterned coating on a surface. After baking for 1 min at 110° C., the photoresist was patterned by UV exposure using a Karl-Suss MA-6 system and a photomask, followed by development with AZ400K developer and standard protocols. 150 nm of Al (or 2 nm Cr/200 nm Au for gold microarray) was then evaporated onto the surface via EBPVD to form the well walls. The photoresist well spots were then removed using acetone, after which an additional 15 nm of aluminum (or 2 nm Cr/50 nm Au) was evaporated to form the well surface. The final microarrays consisted of a 10×10 array of circular wells that were 165 nm (or 250 nm for gold microarray) deep and 600 μm in diameter. In some embodiments, the depth of the wells is from 100-300 nm, with intermediate values of 110 nm, 120 nm, 130 nm, 140 nm, 150 nm, 160 nm, 170 nm, 180 nm, 190 nm, 200 nm, 210 nm, 220 nm, 230 nm, 240 nm, 250 nm, 260 nm, 270 nm, 280 nm and 290 nm, and the diameter of the wells is from 400-800 μm, with intermediate values of 450 μm, 500 μm, 550 μm, 600 μm, 650 μm, 700 μm and 750 μm. The substrates are then mounted on the instrument with a flow-cell for buffer solutions for on-line analysis via any of a range of SPR-based instrumentation.

### Comparative Benefits and Advantages

Due to the spectral features of aluminum, SPR in “fixed angle” mode, which is used in both conventional SPR and imaging configurations, with aluminum films is significantly more natively sensitive than with gold films (by 61.6%) and has a longer working range. Additionally, the native oxide layer of aluminum provides two benefits. First, the chemical reactions possible for immobilization of analyte and related molecules are much broader than for gold. Second, the oxide layer generates a hydration layer that resists the nonspecific binding of hydrophobic materials like those encountered in biological samples, making an aluminum film more robustly anti-fouling than a gold film (by ˜75%). Furthermore, aluminum has several practical manufacturing benefits that make it more commercially appealing than gold, such as higher abundance, lower cost, and easy integration into manufacturing processes such as CMOS.

We have fabricated the substrates in array format and demonstrated the performance improvements over previous microarray materials. We have also demonstrated the use aluminum films on three separate instrument types, NanoSPR, Biacore, and home-built SPR imager.

Various functionalization schemes for aluminum, including silanization, carboxylation and phosphonylation, allow for an expanded range of biological target types. Thin-film configurations include metamaterial forms that allow capture of a broader range of plasmonic-based spectroscopic techniques that have not previously been used with aluminum.

### Example 1

Plasmonic Biosensing with Aluminum Thin Films Under the Kretschmann Configuration

Aluminum has recently attracted considerable interest as a plasmonic material due to its unique optical properties, but most work has been limited to nanostructures. We report here SPR biosensing with aluminum thin-films using the standard Kretschmann configuration (Lambert et al. 2020 “Plasmonic biosensing with aluminum thin films under the Kretschmann configuration” Anal Chem 92: 8654-8659), whereas the standard Kretschmann configuration has previously been dominated by gold films. Electron-beam physical vapor deposition (EBPVD)-prepared Al films oxidize in air to form a nanofilm of Al₂O₃, yielding robust stability for sensing applications in buffered solutions. FDTD simulations revealed a sharp plasmonic dip in the visible range that enables measurement of both angular shift and reflection intensity change at a fixed angle. Bulk and surface tests indicated that Al films exhibited superb sensitivity performance in both categories. Compared to Au, the Al/Al₂O₃ layer showed a marked effect of suppressing nonspecific binding from proteins in human serum. Further characterization indicated that Al film demonstrated a higher sensitivity and a wider working range than Au films when used for SPR imaging analysis. Combined with its economic and manufacturing benefits, the Al thin-film has the potential to become a highly advantageous plasmonic substrate to meet a wide range of biosensing needs in SPR configurations.

### Aluminum Films for Plasmonic Sensing

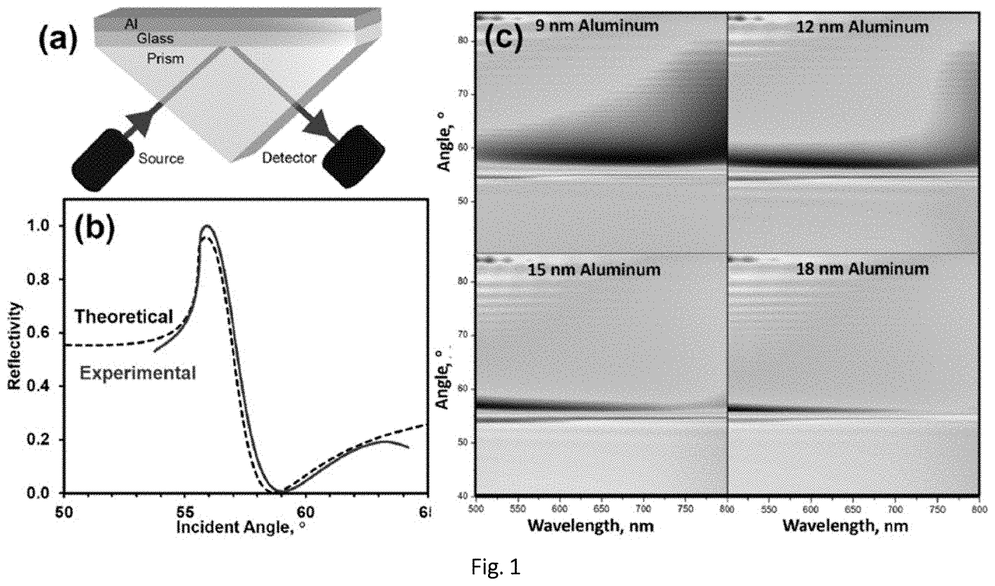

Up until now, the study of aluminum as a plasmonic material has been almost entirely confined to aluminum nanostructures, with a range of reports exploring structures such as nanorods and nanodiscs, among others (Hobbs, R. G.; Manfrinato, V. R.; Yang, Y. J.; Goodman, S. A.; Zhang, L. H.; Stach, E. A.; Berggren, K. K. Nano Lett. 2016, 16 (7), 4149-4157; Zhu, Y.; Nakashima, P. N. H.; Funston, A. M.; Bourgeois, L.; Etheridge, J. ACS Nano 2017, 11 (11), 11383-11392; Liu, J. J.; Yang, L.; Zhang, H.; Wang, J. F.; Huang, Z. F. Small 2017, 13 (39), 1701112; Yang, K. Y.; Butet, J.; Yan, C.; Bernasconi, G. D.; Martin, O. J. F. ACS Photonics 2017, 4 (6), 1522-1530; Rodriguez, R. D.; Sheremet, E.; Nesterov, M.; Moras, S.; Rahaman, M.; Weiss, T.; Hietschold, M.; Zahn, D. R. T. Sens. Actuators, B 2018, 262, 922-927; Su, M. N.; Ciccarino, C. J.; Kumar, S.; Dongare, P. D.; Hosseini Jebeli, S. A.; Renard, D.; Zhang, Y.; Ostovar, B.; Chang, W. S.; Nordlander, P.; Halas, N. J.; Sundararaman, R.; Narang, P.; Link, S. Nano Lett. 2019, 19 (5), 3091-3097; Lee, K. L.; You, M. L.; Wei, P. K. ACS Appl. Nano Mater. 2019, 2 (4), 1930-1939 and Arora, P.; Awasthi, H. V. Prog. Electromagn. Res. M 2019, 79, 167-174). Aluminum as a surface-enhanced Raman scattering (SERS) substrate has also been reported (Taguchi, A.; Hayazawa, N.; Furusawa, K.; Ishitobi, H.; Kawata, S. J. Raman Spectrosc. 2009, 40 (9), 1324-1330; Dorfer, T.; Schmitt, M.; Popp, J. J. Raman Spectrosc. 2007, 38 (11), 1379-1382; and Mogensen, K. B.; Guhlke, M.; Kneipp, J.; Kadkhodazadeh, S.; Wagner, J. B.; Espina Palanco, M.; Kneipp, H.; Kneipp, K. Chem. Commun. 2014, 50 (28), 3744-3746). However, the use of aluminum in the standard configuration for SPR spectroscopy (i.e., Kretschmann configuration), where thin metal films are attached to an attenuated total reflection (ATR) optical coupler, has not been rigorously studied. Some reports investigated the resonances in the ultraviolet region to probe organic and biological systems that exhibit strong UV absorptions (Tanabe, I.; Tanaka, Y. Y.; Watari, K.; Hanulia, T.; Goto, T.; Inami, W.; Kawata, Y.; Ozaki, Y. Chem. Lett. 2017, 46 (10), 1560-1563; and Tanabe, I.; Tanaka, Y. Y.; Watari, K.; Hanulia, T.; Goto, T.; Inami, W.; Kawata, Y.; Ozaki, Y. Sci. Rep. 2017, 7, 5934) while other attempts with aluminum films were impaired by substrate stability issues and failed to generate meaningful results (Oliveira, L. C.; Herbster, A.; da Silva Moreira, C.; Neff, F. H.; Lima, A. M. N. IEEE Sens. J. 2017, 17 (19), 6258-6267). In this work, we describe plasmonic characterization of Al thin films in ATR mode (FIG. 1, (a)), employing both FDTD and the Fresnel models to predict the surface plasmon polariton (SPP) behavior on the aluminum film and conducting an extensive experimental study to understand and verify the fundamental SPR characteristics of the metal. This analysis of Al film is essential to fully expanding the scope of potential biosensing applications, which seek to characterize various SPR refractive index sensing and biosensing performance in the standard Kretschmann configuration.

Initial modeling work was conducted by using a finite difference time domain (FDTD) simulation and the Fresnel equation simulation (FIG. 1). The Fresnel equations determine the proportions of an incident wave that are reflected and transmitted when it strikes the interface of materials with differing refractive indexes. For the Fresnel equations to function, the materials must be universally homogeneous thin films (Kurihara, K.; Suzuki, K. Anal. Chem. 2002, 74 (3), 696-701). FDTD solves for electrical and magnetic fields in all dimensions by defining a Yee cell wherein cell size is dependent on the permittivity and permeability of the material and the time step (Yee, K. S.; Chen, J. S. IEEE Trans. Antennas Propag. 1997, 45 (3), 354-363). Simulation results reveal that aluminum shows a sharp peak in reflectivity before the dip (FIG. 1, (b) and (c)), whereas for gold films, a smooth total internal reflection plateau prior to the plasmonic dip is typically displayed. Using the Lorentz-Drude model (Markovic, M. I.; Rakic, A. D. Appl. Opt. 1990, 29 (24), 3479-3483), this can be ascribed to the higher valence shell charge density of aluminum, i.e., three electrons in its conduction band versus one for gold. This results in a higher metallic plasma frequency ωp, which then results in increased real (n) and imaginary (k) portions of the refractive index (see the Supporting Information). Though the effects of n and k on angular reflectivity dips are complex (Kurihara, K.; Suzuki, K. Anal. Chem. 2002, 74 (3), 696-701), high k-values are strongly correlated with plasmonic dips and increased plasmonic activity. Aluminum's higher n and k values also mean that standard film thicknesses used for Au (45-50 nm) were not applicable to Al, and the FDTD analysis across a wide range of thicknesses indicated that experimental investigation should target the 10-20 nm range (FIG. 1, (c)). In our study, plasmonic aluminum films were fabricated by e-beam depositing Al onto glass slides, with the initial deposited thickness set at 15 nm. The films were stored in air for 3 days in order to ensure a consistent and fully oxidized alumina layer, which can be approximated to a final Al/Al₂O₃ thickness of 12/3 nm. The films were then mounted to a prism for SPR measurement (FIG. 1, (a)). FIG. 1, (b) shows a typical angular reflection spectrum with water using the Al substrate (in gray), which shows excellent agreement to the corresponding theoretical prediction (black dashed line).

### Lorentz-Drude Model Equations

As adapted from Rakic (Markovic, M. I.; Rakic, A. D., Determination of the reflection coefficients of laser-light of wavelengths lambda-epsilon (0.22 mu-m,200 mu-m) from the surface of aluminum using the Lorentz-Drude model. Applied Optics 1990, 29 (24), 3479-3483), the incident angle-independent reflectivity coefficient for a metal film is:

$$R = \frac{{( n - 1 )}^{2} + {k}^{2}}{{( n + 1 )}^{2} + {k}^{2}}$$

The real and imaginary portions of the refractive index n and k, respectively, can themselves be defined in terms of the real and imaginary portions of the metal's relative dielectric function ∈r and ∈i along with the relative magnetic permeability μr:

$$n = \sqrt{\frac{{μ}_{r}}{2} ( \sqrt{{ϵ}_{r}^{2} + {ϵ}_{i}^{2}} + {ϵ}_{r}^{2} )} \\ k = \sqrt{\frac{{μ}_{r}}{2} ( \sqrt{{ϵ}_{r}^{2} + {ϵ}_{i}^{2}} - {ϵ}_{r}^{2} )}$$

The dielectric functions ∈r and ∈i are themselves also defined in terms of the frequency of the incident light ω, the metal plasma frequency ωp, and the metal damping frequency Γ:

$${ϵ}_{r} = 1 - \frac{{ω}_{p}^{2}}{{ω}^{2} + {Γ}^{2}} \\ {ϵ}_{i} = \frac{{ω}_{p}^{2} Γ}{ω ( {ω}^{2} + {Γ}^{2} )}$$

The plasma frequency is then defined as:

$${ω}^{2} p = \frac{N {e}^{2}}{m {ϵ}_{0}}$$

where N is the metal's free electron density, e and m are the charge and mass of an electron, respectively, and ∈0 is the permittivity of free space.

### FDTD and Fresnel-Based Simulations

FDTD based simulations were performed using EM Explorer software.

Simulations were conducted in similar manner to previously reported (Li, H.; Chen, C. Y.; Wei, X.; Qiang, W. B.; Li, Z. H.; Cheng, Q.; Xu, D. K., Highly Sensitive Detection of Proteins Based on Metal-Enhanced Fluorescence with Novel Silver Nanostructures. Anal. Chem. 2012, 84 (20), 8656-8662) and parameters were as follows. Real and imaginary parts of the Al and Al₂O₃ refractive indices across the wavelength spectrum were obtained from the Filmetrics database (Filmetrics Refractive Index Database. http://www.filmetrics.com/refractiveindex-database (accessed December)). The Al thickness was varied from 9 nm to 18 nm, and Al₂O₃ was kept at a consistent 3 nm. The Yee cell size was set to be 5 nm cubes. The light was set to be p-polarized. This was then used to probe the plasmonic activity with 500-800 nm wavelength of light with a range of incident angles from 40-85 degrees.

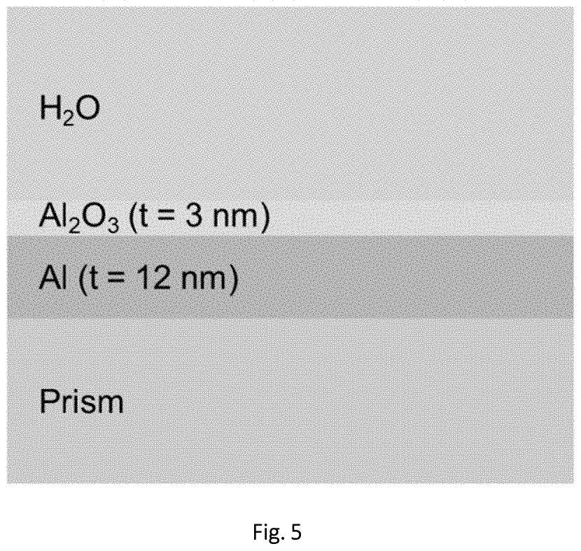

Table 1 lists the optical constants used in the Fresnel-based angular spectrum simulations. Literature sources were used to obtain values of Al and Au (Hagemann, H. J.; Gudat, W.; Kunz, C., Optical constants from the far infrared to the x-ray region: Mg, Al, Cu, Ag, Au, Bi, C, and Al2O3. J. Opt. Soc. Am. 1975, 65 (6), 742-744) and for value of Al₂O₃(Smith, D. Y.; Shiles, E.; Inokuti, M., The Optical Properties of Metallic Aluminum**Work supported by the U.S. Department of Energy. In Handbook of Optical Constants of Solids, Palik, E. D., Ed. Academic Press: Boston, 1985; pp 369-406). Simulation was conducted as previously reported (Tanabe, I.; Tanaka, Y. Y.; Ryoki, T.; Watari, K.; Goto, T.; Kikawada, M.; Inami, W.; Kawata, Y.; Ozaki, Y., Direct optical measurements of far- and deep-ultraviolet surface plasmon resonance with different refractive indices. Optics Express 2016, 24 (19), 21886-21896) and was based on standard Fresnel multi-layer calculation model, the layers of which are shown in FIG. 5. For Au simulation, Al and Al₂O₃ were replaced with 50 nm Au.

TABLE 1
Refractive index values used in Fresnel-based simulations.

| Wavelength | Prism | Al | Al₂O₃ | Au | H₂O |
|---|---|---|---|---|---|
| 650 nm | 1.616 | 1.483 + i7.577 | 1.765 | 0.169 + i3.136 | 1.333 |

### Materials and Reagents

Bovine serum albumin (BSA) was obtained from Sigma-Aldrich (St. Louis, Mo.). Sodium chloride was obtained from Fisher Scientific (Pittsburgh, Pa.). Biotinylated bovine serum albumin (Biotin-BSA) and streptavidin were obtained from Thermo Scientific (Rockford, Ill.). BK-7 glass substrates for deposition were obtained from Corning (Painted Post, NY). Aluminum, gold and chromium targets for electron-beam evaporation were acquired as pellets of 0.9999% purity from Kurt J. Lesker (Jefferson Hills, Pa.). Whole human serum was obtained from Innovative Research (Novi, Mich.) as single donor human serum off the clot.

### SPR and SPR Imaging Substrate Fabrication

Both SPR and SPR imaging substrates were fabricated using BK-7 glass microscope slides as the initial substrate. Slides were cleaned using boiling piranha solution (3:1 H₂SO₄:30% H₂O₂) for 1 hr, followed by rinsing with ultrapure water and ethanol and drying with compressed nitrogen gas. For conventional SPR chips, 15 nm (5.0 Å/s) of aluminum was evaporated onto one side of the slide via electron beam physical vapor deposition. (EBPVD) (Temescal, Berkeley, Calif.). For Au chips, evaporation instead consisted of 2 nm of chromium (0.5 Å/s) and 50 nm of gold (2.0 Å/s). All EBPVD was conducted at 5×10−6 Torr in a Class 1000 cleanroom facility (UCR Center for Nanoscale Science and Engineering).

SPR imaging arrays were fabricated in accordance to previously described methods (Abbas, A.; Linman, M. J.; Cheng, Q., Patterned Resonance Plasmonic Microarrays for High-Performance SPR Imaging. Anal. Chem. 2011, 83 (8), 3147-3152) with some modification. Cleaned glass slides were spin-coated with hexamethyldisilazane (HMDS) to promote adhesion, followed by AZ5214E, both at 4000 RPM for 45 s. After baking for 1 min at 110° C., the photoresist was patterned by UV exposure using a Karl-Suss MA-6 system and a photomask, followed by development with AZ400K developer and standard protocols. 150 nm of Al (or 2 nm Cr/200 nm Au for gold microarray) was then evaporated onto the surface via EBPVD to form the well walls. The photoresist well spots were then removed using acetone, after which an additional 15 nm of aluminum (or 2 nm Cr/50 nm Au) was evaporated to form the well surface. The final microarrays consisted of a 10×10 array of circular wells that were 165 nm (or 250 nm for gold microarray) deep and 600 μm in diameter. Both SPR and SPRi substrates were stored in air for 3 days prior to use.

### Atomic Force Microscopy Measurements

AFM measurements were taken using an AIST-NT instrument with a 42 N/m tip provided by NanoWorld. Data was acquired in tapping mode. Gwyddion 2.55 software was used to analyze the resulting data and determined the root mean squared roughness of the surface to be 0.834 nm.

### SPR and SPR Imaging Analysis

A dual-channel NanoSPR6-321 spectrometer (Nano SPR, Chicago, Ill.) was used for all spectroscopic measurements for conventional SPR. The device used a GaAs semiconductor laser light source (λ=670 nm), a manufacturer-supplied prism of high refractive index (n=1.616) and a 30 μL flow cell. Fabricated chips were inserted, and online analysis was conducted in an angular scanning mode that tracked the resonance angle every 5 s while also collecting the angular spectrum at each point. For bulk refractive index testing, 18 MΩ ultrapure water was flowed at a rate of 5 mL/hr as a baseline and NaCl solutions were flowed over the surface. Sodium chloride solutions were diluted from NaCl salt with ultrapure water, and refractive index of each solution was measured with an Abbe refractometer (American Optics, Buffalo, N.Y.). Intensity measurements were extracted from angular spectra at a constant angle at ˜20% of the maximum to ensure maximum sensitivity for both Al and Au chips. Biosensing experiments were conducted using 1×PBS running buffer at 5 mL/hr at ambient temperature. Concentrations of BSA, biotin-BSA and streptavidin used in analysis were 2 mg/mL, 2 mg/mL, and 500 μg/mL, respectively. Analytes were incubated for 30 min to 2 hr, depending on the experiment, before rinsing, and all solutions besides the whole human serum were diluted in 1×PBS prior to the experiment.

SPR imaging was conducted using a home-built setup, a detailed description of which was reported in previous work (Hinman, S. S.; Ruiz, C. J.; Drakakaki, G.; Wilkop, T. E.; Cheng, Q., On-Demand Formation of Supported Lipid Membrane Arrays by Trehalose-Assisted Vesicle Delivery for SPR Imaging. ACS Appl. Mater. Interfaces 2015, 7 (31), 17122-17130). In brief, each microarray substrate was mounted onto an optical stage that utilized an equilateral SF2 prism (n=1.648) and a 300 μL flow cell. The optical stage was fixed to a rotatable goniometer that allowed manual tuning of the incident angle of a 648 nm incoherent light emitting diode (LED) source that was used for SPR excitation. Reflected images were captured with a cooled 12-bit CCD camera (QImaging Retiga 1300) with a resolution of 1.3 MP (1280×1024 pixels) and 6.7 μm×6.7 μm pixel size. Bulk refractive index testing was conducted similarly to conventional SPR testing. Realtime changes in reflectance upon injection of NaCl analyte solutions were recorded every 300 ms inside the individual well elements, and intensity changes were reported as an average of at least 20 individual wells. Intensity data was normalized by dividing the intensity of p-polarized light by the intensity generated by s-polarized light.

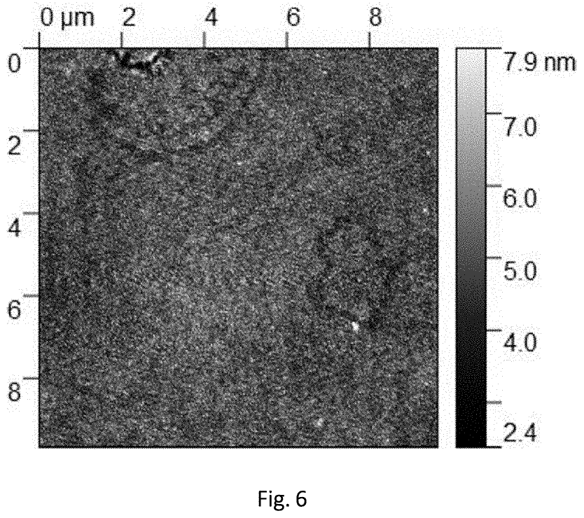

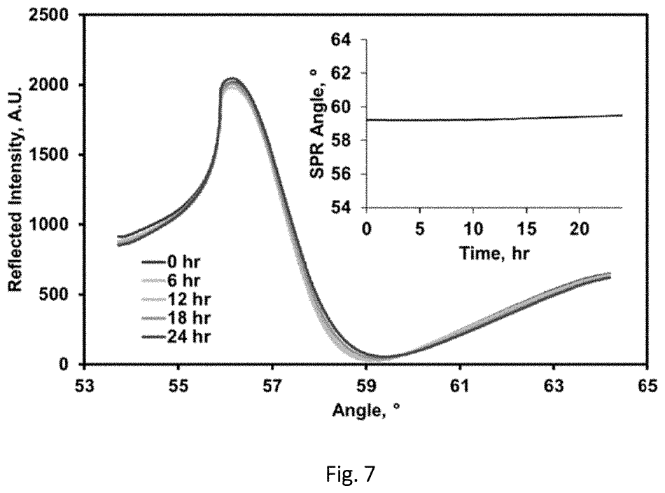

Chemical stability of aluminum in aqueous-based systems is a concern for biosensing applications (Correa, G. C.; Bao, B.; Strandwitz, N. C. ACS Appl. Mater. Interfaces 2015, 7 (27), 14816-14821; and Jha, R.; Sharma, A. K. Opt. Lett. 2009, 34 (6), 749-751) as aluminum is more reactive than other plasmonic materials such as gold and silver and thus can be prone to corrosion. We tested the stability of the deposited aluminum surface using 1× phosphate-buffered saline (PBS) (FIG. 7). Continuous flowing of PBS buffer over 24 h did not significantly alter the shape of the spectrum, and the plasmonic dip did not show noticeable drift over the same period. Soaking the chips in 10×PBS buffer for 24 h also resulted in essentially no visible changes in the surface or resulting spectra. This indicates the formed aluminum oxide overlayer is an effective protection layer to prevent corrosion across the typical time scale of biosensing experiments (1-8 h). Atomic force microscopy (AFM) of the surface after native oxidation shows an RMS surface roughness of 1.5 nm (FIG. 6), suggesting the oxidized surface is highly uniform and thus ideal for binding studies in SPR analysis.

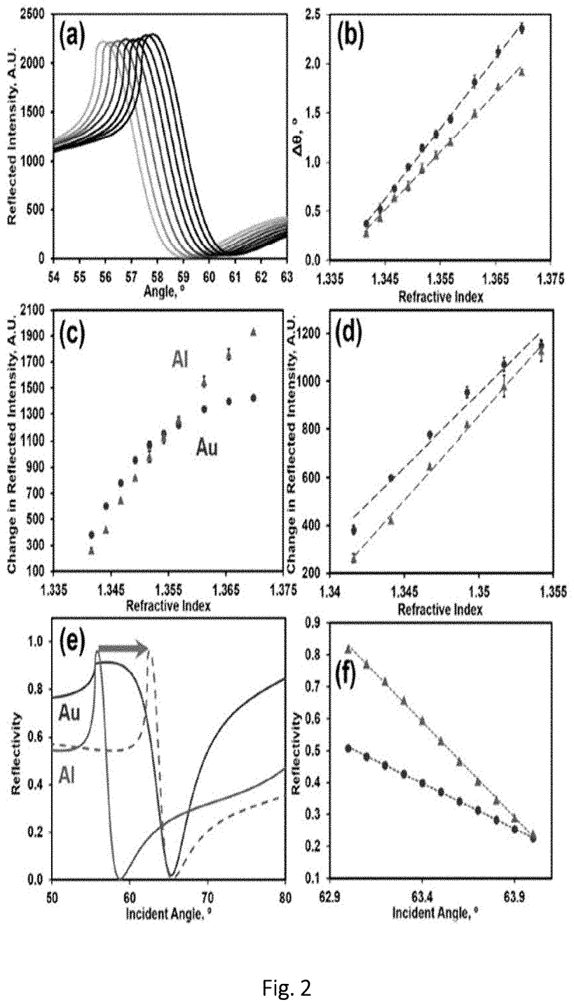

SPR sensitivity characterization for the aluminum film consists of two parts: bulk and surface. A bulk sensitivity test was conducted with NaCl solution in various concentrations flowed over the surface. Angular spectra of a range of solutions are displayed in FIG. 2a. Tracking the shift in the minimum of the dip yields a calibration curve of resonant angle shifts versus refractive index, displayed in FIG. 2b (triangles). Clearly, bulk test showed a good linear response with the Al substrate. From the curve, we determined the sensitivity with angular scanning to be 59.25°/RIU for the 15 nm Al film.

From the reflection spectra, the resonance band appears to be steeper than that of gold (FIG. 2, (e)). Therefore, we next moved to quantify the intensity changes at a fixed angle, a strategy that is frequently used (Puiu, M.; Bala, C. Sensors 2016, 16 (6), 870; and Brockman, J. M.; Nelson, B. P.; Corn, R. M. Annu. Rev. Phys. Chem. 2000, 51, 41-63) and is generally simpler to track (FIG. 2, (c) and (d)). At a fixed angle, aluminum shows both a higher sensitivity (70041 IU/RIU, 13.9% higher than Au) and a much longer linear range (˜0.028 vs ˜0.013 RIU) than gold. For angular shift measurement, however, Au film shows a slightly better reported sensitivity (FIG. 2, (b)). This is largely because the aluminum's plasmonic dip is broader compared to that of gold and more complex than the gold band, compromising the angular shift tracking reliability by the instrument. The varied sensitivity trend between the fixed angle and the angle-shift data is a direct result of the spectral features of the plasmonic responses of the metal films, as shown in FIG. 2, (e) and (f). The steep slope of the plasmonic dip for aluminum suggests it is particularly suited for fixed angle measurements where greater angle reflectance change leads to better sensitivity.

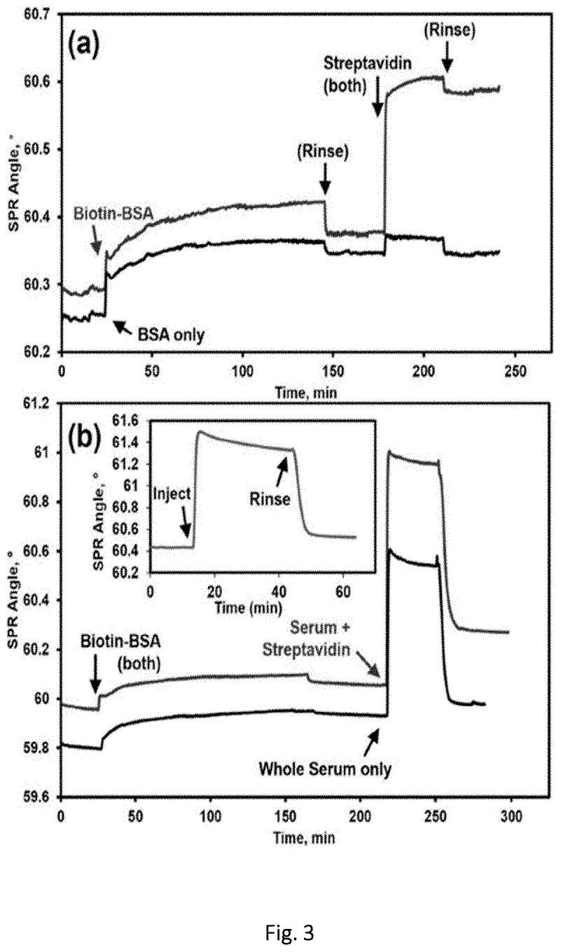

The characterization of SPR biosensing performance, i.e., surface sensitivity, was conducted by the well-characterized biological interaction between biotin and streptavidin. As shown in FIG. 3, (a), biotinylated bovine serum albumin (biotin-BSA) was incubated on the sensing surface followed by injection of streptavidin. A significant binding shift was observed after the final rinse, while in a control channel where BSA was not biotinylated resulted in little angular shift in the streptavidin step, indicating that biological affinity interactions at the surface were the sole source of the binding signal. The binding signal was stable and is consistent with Au film-based SPR experiments reported throughout literature (Perez-Luna, V. H.; O'Brien, M. J.; Opperman, K. A.; Hampton, P. D.; Lopez, G. P.; Klumb, L. A.; Stayton, P. S. J. Am. Chem. Soc. 1999, 121 (27), 6469-6478; Haussling, L.; Ringsdorf, H.; Schmitt, F. J.; Knoll, W. Langmuir 1991, 7 (9), 1837-1840; Cui, X. Q.; Pei, R. J.; Wang, X. Z.; Yang, F.; Ma, Y.; Dong, S. J.; Yang, X. R. Biosens. Bioelectron. 2003, 18 (1), 59-67; and Kim, H.; Cho, I. H.; Park, J. H.; Kim, S.; Paek, S. H.; Noh, J.; Lee, H. Colloids Surf, A 2008, 313, 541-544) This indicates that the fundamentals of protein attachment, surface sensitivity, and subsequent biosensing are equally accessible on the Al films.

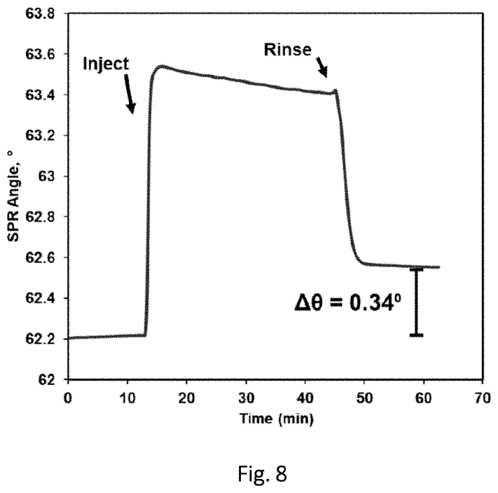

An interesting aspect of aluminum films for plasmonic sensing is their lack of “stickiness” toward biological components such as proteins and lipids, as cell membrane mimics were reported to adhere much more slowly to an Al/Al₂O₃ surface than to a silica or gold surface (Jackman, J. A.; Tabaei, S. R.; Zhao, Z. L.; Yorulmaz, S.; Cho, N. J. ACS Appl. Mater. Interfaces 2015, 7 (1), 959-968; and van Weerd, J.; Karperien, M.; Jonkheijm, P. Adv. Healthcare Mater. 2015, 4 (18), 2743-2779). We observed when undiluted human blood serum was incubated over the surface and was followed by rinsing, very little nonspecific binding signal remained (FIG. 3, (b) inset), a reduction by more than 75% as compared with a gold chip under similar conditions (FIG. 8). This potential antifouling function of the Al/Al₂O₃ surface could be of great use in biosensing in complex media. FIG. 3, (b) shows the sensorgrams with spiked streptavidin in undiluted serum. Subtracting a control of only blood serum, the specific binding signal was only slightly smaller in serum (0.17°) than in buffer (0.21°). This is a remarkable result for a plain surface without any antifouling modifications or steps. Overcoming nonspecific binding is a strong challenge in implementation for all types of plasmonic based biosensors. A large amount of work by our group and others (Rodriguez Emmenegger, C.; Brynda, E.; Riedel, T.; Sedlakova, Z.; Houska, M.; Alles, A. B. Langmuir 2009, 25 (11), 6328-6333; Liu, B. S.; Liu, X.; Shi, S.; Huang, R. L.; Su, R. X.; Qi, W.; He, Z. M. Acta Biomater. 2016, 40, 100-118; McKeating, K. S.; Hinman, S. S.; Rais, A. N.; Zhou, Z. G.; Cheng, Q. ACS Sensors 2019, 4 (7), 1774-1782; Lofas, S.; Johnsson, B.; Edstrom, A.; Hansson, A.; Lindquist, G.; Hillgren, R. M. M.; Stigh, L. Biosens. Bioelectron. 1995, 10 (9-10), 813-822; Zheng, X. J.; Zhang, C.; Bai, L. C.; Liu, S. T.; Tan, L.; Wang, Y. M. J. Mater. Chem. B 2015, 3 (9), 1921-1930; Vaisocherova, H.; Yang, W.; Zhang, Z.; Cao, Z. Q.; Cheng, G.; Piliarik, M.; Homola, J.; Jiang, S. Y. Anal. Chem. 2008, 80 (20), 7894-7901; Liu, J. T.; Chen, C. J.; Ikoma, T.; Yoshioka, T.; Cross, J. S.; Chang, S. J.; Tsai, J. Z.; Tanaka, J. Anal. Chim. Acta 2011, 703 (1), 80-86; Terao, K.; Hiramatsu, S.; Suzuki, T.; Takao, H.; Shimokawa, F.; Oohira, F. Anal. Methods 2015, 7 (16), 6483-6488; Luz, J. G. G.; Souto, D. E. P.; Machado-Assis, G. F.; de Lana, M.; Kubota, L. T.; Luz, R. C. S.; Damos, F. S.; Martins, H. R. Sens. Actuators, B 2015, 212, 287-296; Masson, J. F.; Battaglia, T. M.; Khairallah, P.; Beaudoin, S.; Booksh, K. S. Anal. Chem. 2007, 79 (2), 612-619 and Beeg, M.; Nobili, A.; Orsini, B.; Rogai, F.; Gilardi, D.; Fiorino, G.; Danese, S.; Salmona, M.; Garattini, S.; Gobbi, M. Sci. Rep. 2019, 9, 2064) has been conducted in order to use Au chips with complex matrixes such as blood serum, but Al chips will require much less of this type of effort in their use.

The spectral characteristics of the aluminum films in fixed-angle monitoring also make it an excellent candidate for SPR imaging. SPR imaging measures at a fixed angle, and the only monitored parameter is reflection intensity (Puiu, M.; Bala, C. Sensors 2016, 16 (6), 870). As the method enables the capturing of a wide swath of analysis spots, SPR imaging is frequently used with arrays, significantly improving throughput and multiplexing capabilities of SPR spectroscopy (Scarano, S.; Mascini, M.; Turner, A. P. F.; Minunni, M. Biosens. Bioelectron. 2010, 25 (5), 957-966).

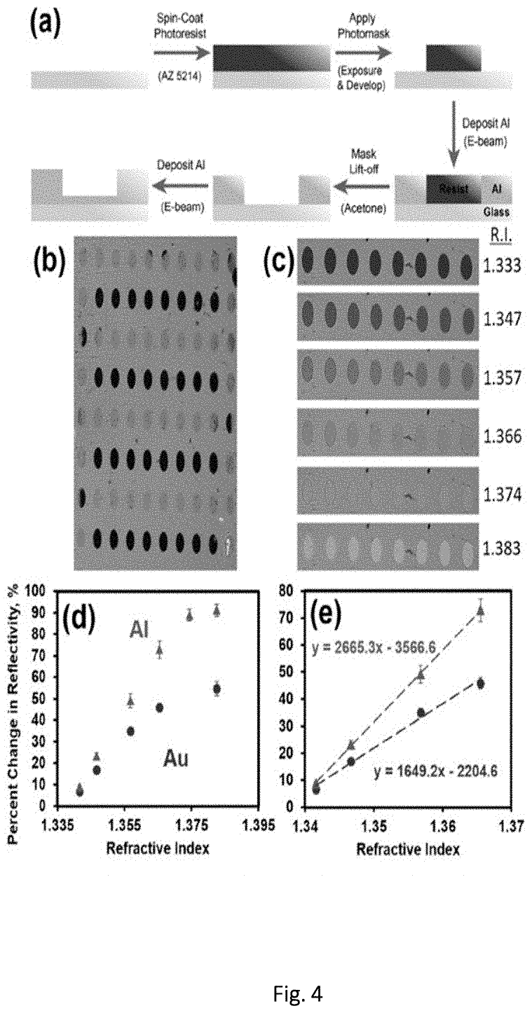

To test this potential use of aluminum thin films, we fabricated an aluminum microarray for SPR imaging adapted from a design that we have described previously (Abbas, A.; Linman, M. J.; Cheng, Q. A. Anal. Chem. 2011, 83 (8), 3147-3152). A summary of the fabrication is displayed in FIG. 4, (a). This includes photolithographic patterning and multiple deposition steps, which serve to create 15 nm-thick wells of 800 nm diameter with 150 nm thick walls. The 150 nm thick aluminum layer dampens effective plasmonic absorption, leaving the microwells the only plasmonically active areas.

As shown in FIG. 4, (b) and (c), the wells were clearly distinguishable from the background surface, indicating that the plasmonic activity was effectively dampened. FIG. 4, (b) shows the online imaging of the well substrate at an angle (58°) of high plasmonic absorption in water (RI=1.333). Bulk sensitivity testing was conducted similarly to the spectral SPR analysis, and images of the changes in the microwell intensities by varying refractive index are shown in FIG. 4, (c). A calibration curve was again constructed and compared to gold (FIG. 4, (d) and (e)). The sensitivity figure of merit for the aluminum film is 2665% IU/RIU, which is 61.6% higher than that of the gold film (1649% IU/RIU). The high response of aluminum again proves its excellent potential for SPR imaging-based biosensing and bioanalysis.

In conclusion, we have demonstrated the feasibility of using thin aluminum films for SPR analyses that are currently almost exclusively conducted by gold films. The Al films can be fabricated by straightforward deposition techniques and show high stability toward solutions of significant salt concentrations, an important consideration as compared to very stable Au films. Bulk sensitivity characterization indicates good plasmonic response comparable or even better than that of Au films, especially when measured at a fixed angle. The surface was responsive to biosensing behavior while exhibiting antifouling behavior, suppressing significant nonspecific interactions. Aluminum is also amenable to generating background-free SPR imaging substrates of similar bulk refractive index sensitivity. Furthermore, Al₂O₃ has a broad range of established functionalization pathways for the immobilization of biomolecules, such as silanization (Sin, E. J.; Moon, Y. S.; Lee, Y. K.; Lim, J. O.; Huh, J. S.; Choi, S. Y.; Sohn, Y. S. Biomed. Eng. 2012, 24 (02), 111-116; Saleema, N.; Sarkar, D. K.; Gallant, D.; Paynter, R. W.; Chen, X. G. ACS Appl. Mater. Interfaces 2011, 3 (12), 4775-4781; and Kurth, D. G.; Bein, T. Langmuir 1995, 11 (8), 3061-3067), carboxylation (Karaman, M. E.; Antelmi, D. A.; Pashley, R. M. Colloids Surf, A 2001, 182 (1-3), 285-298; Lim, M. S.; Feng, K.; Chen, X. Q.; Wu, N. Q.; Raman, A.; Nightingale, J.; Gawalt, E. S.; Korakakis, D.; Hornak, L. A.; Timperman, A. T. Langmuir 2007, 23 (5), 2444-2452; and Al-Shatty, W.; Lord, A. M.; Alexander, S.; Barron, A. R. Acs Omega 2017, 2 (6), 2507-2514) and phosphonylation (Spori, D. M.; Venkataraman, N. V.; Tosatti, S. G. P.; Durmaz, F.; Spencer, N. D.; Zurcher, S. Langmuir 2007, 23 (15), 8053-8060; Hogue, E.; DeRose, J. A.; Kulik, G.; Hoffmann, P.; Mathieu, H. J.; Bhushan, B. J. Phys. Chem. B 2006, 110 (22), 10855-10861; and Liakos, I. L.; McAlpine, E.; Chen, X. Y.; Newman, R.; Alexander, M. R. Appl. Surf. Sci. 2008, 255 (5), 3276-3282), which can be used in a similar manner to that of the common thiolation-based Au surface functionalization (Sigal, G. B.; Bamdad, C.; Barberis, A.; Strominger, J.; Whitesides, G. M. Anal. Chem. 1996, 68 (3), 490-497). This work demonstrates exciting plasmonic properties of Al in the context of SPR analysis.

### Example 2

### Expanding Bioanalysis Capability of the Plasmonic Aluminum Thin Films with Chemical Modification and Surface Enhanced MALDI-MS

The plasmonic properties of aluminum films as the interface substrates for a wider range of analytical platforms were investigated for both SPR biosensing and MALDI-MS. The unmodified Al film was shown to be effective for enriching phosphorylated peptides from milk proteins for mass spectrometric profiling. Using ionic polymers, we analyzed charge-based binding interactions for both large macromolecules (lipid vesicles) and medically relevant biomarkers. The qualitative separation of charged lipid vesicles by ionic polymers could be monitored and showed selectivity over the bare Al surface. In SPR imaging mode, the high sensitivity of aluminum allowed for quantification of kinetic differences of charge-based binding interactions between ionic polymers and biomarker peptides CXCL8 and CXCL10. The binding effects were found to be correlated to the charge densities of the biomarkers and the charged polymers. In addition, the use of artificial urine matrix altered the association behavior in a defined manner. MALDI-MS ionization of the biomarkers was found to be affected by the polymer coating. Nevertheless, comparison to spectra of the same biomarkers obtained on a conventional steel plate and on an Au plate indicates that aluminum plates have m/z intensity values significantly higher than those on steel plate or an Au film, supporting the assertion that the plasmonic absorption of the aluminum of the UV laser (337 nm) of the MALDI enhances the MS signals. Finally, the functionalization of the Al₂O₃ overlayer by silanization was investigated for selective binding of bacterial protein streptavidin in SPR analysis, demonstrating a first, successful chemical functionalization for SPR biosensing that did not use Au or Ag. We believe that Al film based bioanalytical techniques are of great potential and can have a vast benefit for future study of the complexities of biophysical interactions. Experimental Methods

Materials and Reagents. Aluminum targets for electron beam physical vapor deposition (EBPVD) were obtained as pellets of 0.9999% purity from Kurt J. Lesker (Jefferson Hills, Pa.). BK-7 glass substrates for E-Beam deposition were obtained from Corning (Painted Post, NY). Polyallylamine hydrochloride (PAH) was obtained from Alfa Aesar (Haverhill, Mass.). Biotin-PEG(2K)-silane was obtained from Nanosoft Polymers (Winston-Salem, N.C.). 1-Palmitoyl-2-oleoyl-glycero-3-phosphocholine (POPC), 1,2-dioleoyl-sn-glycero-3-ethylphosphocholine (EPC), and 1-palmitoyl-2-oleoyl-sn-glycero-3-phospho-(1′-rac-glycerol) (POPG) were obtained as powder from Avanti Polar Lipids (Alabaster, Ala.). CXCL8 and CXCL10 proteins were obtained as powder from Sino Biological (Wayne, Pa.). Acetonitrile, sucrose, potassium chloride, sodium chloride, calcium chloride, sodium phosphate monobasic, and sodium phosphate dibasic were obtained from Fisher Scientific (Pittsburgh, Pa.). Polyacrylic acid (PAA), poly-L-lysine (PLL), polystyrene sulfonate (PSS), “super” 2,5-Dihydroxybenzoic acid (sDHB), α-cyano-4-hydroxycinnamic acid (CHCA), phosphoric acid (H₃PO₄), trifluoroacetic acid (TFA), trypsin, bovine α-casein and β-casein, sodium sulfate, uric acid, sodium citrate, creatinine, urea, ammonium chloride, potassium oxalate, and magnesium sulfate were obtained from Sigma-Aldrich (St. Louis, Mo.).

Artificial Urine Preparation. Artificial urine matrix for biosensing experiments was prepared according to a previously published protocol (Sarigul, N.; Korkmaz, F.; Kurultak, I., A New Artificial Urine Protocol to Better Imitate Human Urine. SCIENTIFIC REPORTS 2019, 9). Component chemicals were added as solids at the concentrations provided there to ultrapure DI H₂O held at 38° C. under constant stirring. Solution pH was measured to be 6.0±0.1 by a UB-5 pH meter (Denver Instruments, Arvada, Colo.), and solutions were kept for one week and tested for pH and refractive index shifts before each use.

Fabrication and modification of thin film substrates. Conventional SPR and SPR imaging/array substrates were fabricated with BK-7 glass microscope slides that were cleaned with boiling piranha solution (3:1 H₂SO₄:30% H₂O₂) for 1 hr then rinsed with ultrapure water and ethanol and dried with compressed air. An Electron beam physical vapor deposition (EBPVD) system (Temescal, Berkeley, Calif.) was used to deposit all Al films, and all EBPVD was conducted in a Class 1000 cleanroom facility (UCR Center for Nanoscale Science and Engineering). For conventional SPR substrates, 18 nm Al was deposited.

Microarray substrates used for SPR imaging and MALDI-MS were fabricated along previously reported procedures (Abbas, A.; Linman, M. J.; Cheng, Q. A., Patterned Resonance Plasmonic Microarrays for High-Performance SPR Imaging. Analytical Chemistry 2011, 83 (8), 3147-3152). In brief, piranha-cleaned glass slides were spin-coated at 4000 RPM for 45 s with hexamethyldisilazane (HMDS) and AZ5214E in succession, followed by a 1 min bake at 110° C. Photopatterning via UV exposure was conducted with a photomask and Karl-Suss MA-6 system followed by AZ400K development using standard protocols. 150 nm Al was deposited by EBPVD, followed by removal of wells with acetone. An additional deposition of 18 nm Al was lastly added to generate the plasmonically active layer in the wells. The final array was a 10×12 set of 600 μm diameter circular wells. For both conventional and imaging substrates, chips were stored under vacuum until experimental use.

For polymer surface modifications, individual aluminum chips used for conventional SPR were immersed in ˜5 mL aliquots of solutions of a single polymer diluted to 10 mg/mL in ultrapure DI H₂O for 5 min, rinsed, and repeated before use. In array configurations for SPR imaging and MALDI-MS, solutions of each polymer were spotted onto individual wells in 0.5 μL aliquots, allowed to dry, then rinsed and repeated before use. For chemical functionalization, Al/Al₂O₃ chip substrates were immersed in a 1 mM solution of biotin-PEG(2K)-silane in EtOH overnight (12 hr) with mild agitation, followed by isopropanol rinse and N₂ drying.

MALDI-TOF-MS analysis. Tryptic digestions of α-casein and β-casein were conducted under standard conditions in 1×PBS buffer. Solutions of 200 μg/mL of analyte protein were boiled at 100° C. for 1 min to denature the protein. Next, the analyte solution and 5 μg/mL of trypsin were mixed in a 4:1 ratio, respectively, and were heated in a water bath at 38° C. overnight (15 hr), then quenched by addition of 0.1% TFA in a 1:10 ratio. For on-chip enrichment of peptide peaks, ˜1 μL of resulting mixture was spotted onto individual microarray wells and allowed to sit in a humidity chamber for 30 minutes to reduce evaporation. Microarray wells were then further washed with 0.1% TFA three times for 5 min each. MALDI matrix consisting of 10 mg/mL sDHB in a 1:1 mixture of 1% H₃PO₄ and acetonitrile was spotted and allowed to dry. MALDI-MS spectra for peptide peaks were obtained using an AB-Sciex 5800 MALDI-TOF instrument in positive reflector ion mode. Spectra were compiled and analyzed for m/z peaks with a greater than 3 S/N ratio by an in-lab Matlab package described in a previous report (Li, B.; Stuart, D. D.; Shanta, P. V.; Pike, C. D.; Cheng, Q., Probing Herbicide Toxicity to Algae (Selenastrum capricornutum) by Lipid Profiling with Machine Learning and Microchip/MALDI-TOF Mass Spectrometry. Chemical Research in Toxicology 2022, 35 (4), 606-615) and peptide profiles were analyzed using Expasy FindPept tool (Gattiker, A.; Bienvenut, W. V.; Bairoch, A.; Gasteiger, E., FindPept, a tool to identify unmatched masses in peptide mass fingerprinting protein identification. PROTEOMICS 2002, 2 (10), 1435-1444). For polymer-coated microarrays without SPR imaging coupling, solutions of each or both chemokine biomarker were spotted onto individual polymer-coated wells. This was followed by spotting of MALDI matrix consisting of 10 mg/mL CHCA dissolved in a 1:1 mixture of 0.5% TFA and acetonitrile.

Mass Spectra were Obtained in in Linear Positive Mode at a Laser Fluency of 5500 Au on the Same Instrument as Above.

SPR and SPR imaging. Conventional SPR experiments were conducted using a dual-channel NanoSPR6-321 spectrometer equipped with a GaAs semiconductor laser light source (λ=670 nm), a manufacturer supplied reflector prism (n=1.616), and a 30 μL flow cell. Experimental data and sensorgrams were conducted in angular scanning mode, which measured minimum reflected intensity over time. For SPR imaging, measurements were conducted on a home-built experimental setup, a detailed description of which was reported previously (Wilkop, T.; Wang, Z. Z.; Cheng, Q., Analysis of mu-contact printed protein patterns by SPR imaging with a LED light source. Langmuir 2004, 20 (25), 11141-11148). Briefly, aluminum substrate microarrays were mounted onto an SF2 glass 25 mm equilateral triangular prism (n=1.648) with a layer of high-refractive index matching fluid to facilitate even contact. A 3D printed optical stage and flow-cell holder allowed mounting of a 300 μL S-shaped flowcell that covered four primary well rows and two half-rows during online experiments. The optical stage was fixed atop a goniometer that could be manually rotated to tune the incident angle of incoming light from an incoherent light emitting diode (LED) source (λ=648 nm) that could be either p- or s-polarized by a rotatable polarizer. Reflected images from the array were captured with a cooled 12-bit CCD camera (QImaging Retiga 1300) with a resolution of 1.3 MP (1280×1024 pixels) and 6.7 μm×6.7 μm pixel size. Online experimental data acquisition consisted of recording the p-polarized reflected intensity of each well (regions of interest manually selected) every 300 ms during baselining, injection and incubation of analyte solutions, and rinse cycles, followed by an acquisition of the s-polarized intensity. Intensity data was normalized in two ways. First, the p-polarized intensity was divided by the intensity of s-polarized intensity then multiplied by 100 to generate a percentage value. Second, during array-based experiments using polymers, a control channel was used to normalize intensities across experiments. Final percent intensity values are reported as the average of at least 6 wells per channel per experiment, resulting in ˜20 wells per reported value. Solutions of sucrose and sodium chloride for bulk sensitivity testing were diluted with ultrapure DI H₂O and their refractive indices were measured with an abbe refractometer (American Optics, Buffalo, N.Y.). Lipid vesicles used in conventional SPR experiments were generated by pipetting lipids stored in 9:1 chloroform:methanol to a 1 mg/mL concentration, drying under N₂ and placing in vacuum for 4 hr, followed by dilution with buffer, sonication, and extrusion into 100 nm lipid vesicles (Whatman 100 nm membrane filters). For SPR-MALDI coupling analyses of chemokines, after analytes were incubated and rinsed, the microarray chip was removed from the SPR imaging setup and allowed to dry. MALDI matrix of 10 mg/mL CHCA in 1:1 0.5% TFA:ACN was spotted and arrays were mounted and MALDI analyzed as detailed above.

### Results and Discussion

Al₂O₃-Mediated Enrichment of Phosphorylated Peptides

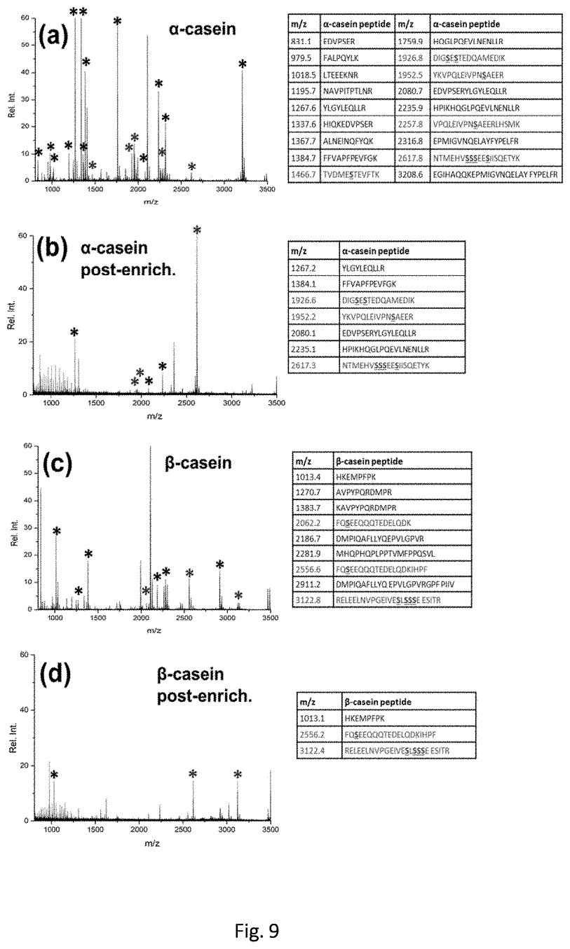

Alpha and beta casein's presence in dairy products make them common sources of phosphorylated peptides in human diets, so their enrichment and quantification are highly investigated (Guo, J. P.; Li, S. J.; Wang, S.; Wang, J. P., Determination of Trace Phosphoprotein in Food Based on Fluorescent Probe-Triggered Target-Induced Quench by Electrochemiluminescence. JOURNAL OF AGRICULTURAL AND FOOD CHEMISTRY 2020, 68 (45), 12738-12748; Xiao, J.; Yang, S. S.; Wu, J. X.; Wang, H.; Yu, X. Z.; Shang, W. B.; Chen, G. Q.; Gu, Z. Y., Highly Selective Capture of Monophosphopeptides by Two-Dimensional Metal-Organic Framework Nanosheets. ANALYTICAL CHEMISTRY 2019, 91 (14), 9093-9101; Qiao, L.; Roussel, C.; Wan, J. J.; Yang, P. Y.; Girault, H. H.; Liu, B. H., Specific on-plate enrichment of phosphorylated peptides for direct MALDI-TOF MS analysis. JOURNAL OF PROTEOME RESEARCH 2007, 6 (12), 4763-4769; Ashley, J.; Shukor, Y.; D'Aurelio, R.; Trinh, L.; Rodgers, T. L.; Temblay, J.; Pleasants, M.; Tothill, I. E., Synthesis of Molecularly Imprinted Polymer Nanoparticles for alpha-Casein Detection Using Surface Plasmon Resonance as a Milk Allergen Sensor. ACS SENSORS 2018, 3 (2), 418-424; and Hung, Y. L. W.; Chen, X. F.; Wong, Y. L. E.; Wu, R.; Chan, T. W. D., Development of an All-in-One Protein Digestion Platform Using Sorbent-Attached Membrane Funnel-Based Spray Ionization Mass Spectrometry. JOURNAL OF THE AMERICAN SOCIETY FOR MASS SPECTROMETRY 2020, 31 (10), 2218-2225). We have previously reported nanostructured TiO₂-based arrays for the on-plate enrichment of phosphopeptides and MALDI-MS analysis (Wang, H.; Duan, J. C.; Cheng, Q., Photocatalytically Patterned TiO₂ Arrays for On-Plate Selective Enrichment of Phosphopeptides and Direct MALDI MS Analysis. ANALYTICAL CHEMISTRY 2011, 83 (5), 1624-1631), and the aluminum array substrate should also be selective for phosphorylated peptides, as the phosphate group coordinates with the oxygens of the surface Al₂O₃. Both α-casein and β-casein were tryptically digested and deposited onto Al thin film microarrays both with a series of enrichment and washing steps in a lightly acidic environment to promote phosphate groups binding to the Al₂O₃. This was compared to a simple deposition and washing to highlight the effect of the enrichment steps. Comparisons of averaged spectra are shown in FIG. 9 along with lists of identified casein peptides. In both cases, the proportion of phosphorylated peaks dramatically increases after enrichment, from 28% to 43% for α-casein and from 33% to 66% for β-casein. Notably, all peptides initially identified with multiple phosphorylation sites (DIG [symbol] E [symbol] TEDQAMEDIK (SEQ ID NO: 1) and NTMEHV [symbol] EESIISQETYK (SEQ ID NO: 2) for α-casein and RELEELNVPGEIVE [symbol] L [symbol] EESITR (SEQ ID NO: 3) for β-casein) were retained after enrichment and washing steps, indicating that the enrichment is at least somewhat chemically driven. Significant optimization can be conducted for retention of even more phosphorylated peaks, but this represents the first report of this type of enrichment being successfully conducted on plasmonically active Al thin films.

### Qualitative Separation of Charged Vesicles Via Ionic Polymer Surface Modification

After confirming the utility of bare Al/Al₂O₃, we moved to physical surface modification. As a measure of the qualitative feasibility of charge-based separation of binding signals, lipid vesicles of varying composition were tested for their binding to surfaces of different charge. Binding and fusion of lipid vesicles and membranes to a surface is highly dependent on surface material characteristics (Liu, J. W.; Jiang, X. M.; Ashley, C.; Brinker, C. J., Electrostatically Mediated Liposome Fusion and Lipid Exchange with a Nanoparticle-Supported Bilayer for Control of Surface Charge, Drug Containment, and Delivery. J. Am. Chem. Soc. 2009, 131 (22), 7567-+; Tero, R.; Takizawa, M.; Li, Y. J.; Yamazaki, M.; Urisu, T., Lipid membrane formation by vesicle fusion on silicon dioxide surfaces modified with alkyl self-assembled monolayer islands. LANGMUIR 2004, 20 (18), 7526-7531; Hardy, G. J.; Nayak, R.; Zauscher, S., Model cell membranes: Techniques to form complex biomimetic supported lipid bilayers via vesicle fusion. CURRENT OPINION IN COLLOID & INTERFACE SCIENCE 2013, 18 (5), 448-458; and Cho, N. J.; Frank, C. W.; Kasemo, B.; Hook, F., Quartz crystal microbalance with dissipation monitoring of supported lipid bilayers on various substrates. NATURE PROTOCOLS 2010, 5 (6), 1096-1106); for example, the addition of a silica layer to Au thin films reverses lipid bilayer fusion from poor to excellent (Phillips, K. S.; Wilkop, T.; Wu, J. J.; Al-Kaysi, R. O.; Cheng, Q., Surface plasmon resonance imaging analysis of protein-receptor binding in supported membrane arrays on gold substrates with calcinated silicate films. J. Am. Chem. Soc. 2006, 128 (30), 9590-9591). Thus, relative changes in binding should be distinguishable here. Lipid vesicles are popular for a variety of bioanalytical purposes, but here they have the benefit of being easily tunable for the desired surface charge. Different lipid head groups compositions serve to present essentially unified exteriors of positive, negative or zwitterionic charge. It should be noted that aluminum oxide has a slightly negative surface charge in aqueous conditions at physiological pH, as the surface oxide becomes slightly hydrolyzed (Brinker, C. J., HYDROLYSIS AND CONDENSATION OF SILICATES—EFFECTS ON STRUCTURE. JOURNAL OF NON-CRYSTALLINE SOLIDS 1988, 100 (1-3), 31-50), which the case here with 1×PBS running buffer.

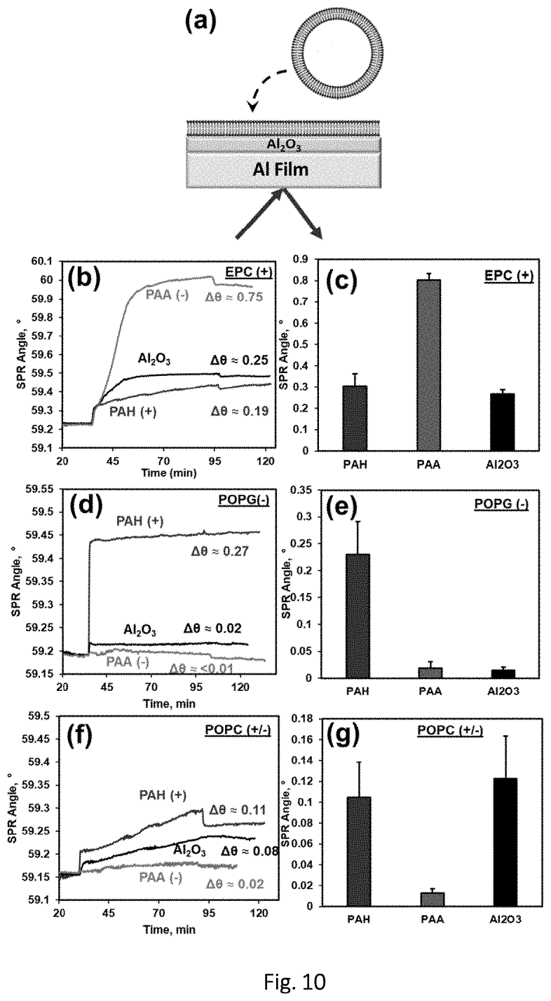

Individual sensorgrams are shown in FIG. 10, (b), (d), and (f) of each surface to vesicle combination. The most striking initial feature is the binding signal for the EPC and POPG vesicles is substantially higher for the surface of opposite charge than for either the Al₂O₃ or the similarly charged surface. There is little binding of the POPC vesicles to any of the three surfaces, which supports the need for a specific lipid-surface interaction for significant fusion to occur. Notably, the Al₂O₃ surface did not have a vesicle of any composition that preferentially bound to it over either the PAH or PAA, a characteristic observed previously by us and others that is attributed to a strong hydration layer (Jackman, J. A.; Tabaei, S. R.; Zhao, Z. L.; Yorulmaz, S.; Cho, N. J., Self-Assembly Formation of Lipid Bilayer Coatings on Bare Aluminum Oxide: Overcoming the Force of Interfacial Water. ACS Appl. Mater. Interfaces 2015, 7 (1), 959-968; and van Weerd, J.; Karperien, M.; Jonkheijm, P., Supported Lipid Bilayers for the Generation of Dynamic Cell-Material Interfaces. Adv. Healthc. Mater. 2015, 4 (18), 2743-2779). A more quantitative comparison of the various binding combinations is given in FIG. 10, (c), (e) and (g), that shows similar trends.

### Microarray Analysis of Urine Biomarker Binding Dynamics

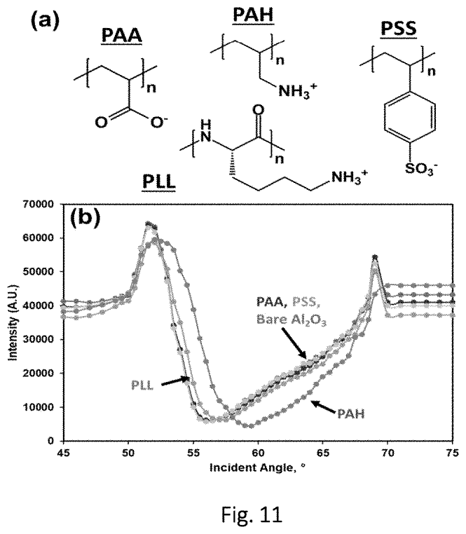

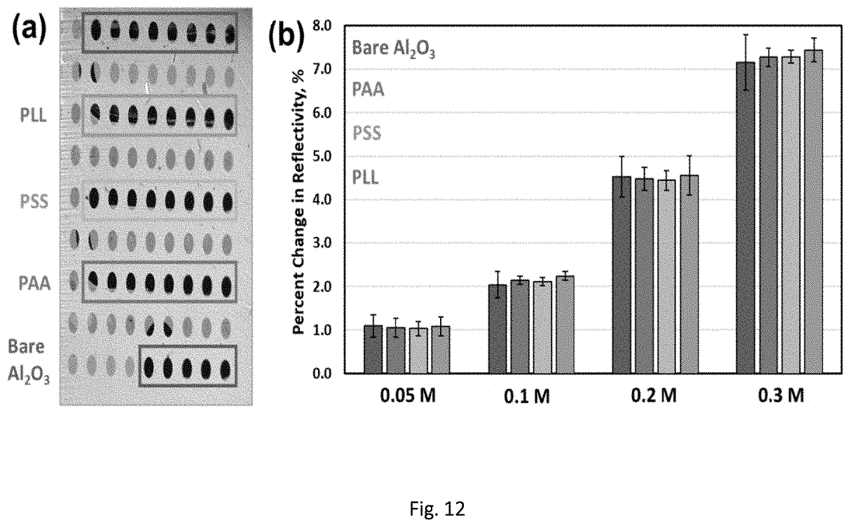

Microarray-based bioanalysis is ideal for the high sensitivity of Al thin films for SPR imaging, so the charge separation was further interrogated using large peptide biomarkers. Urine biomarker panels are an increasingly popular means of diagnosing kidney, bladder, and prostate diseases and injuries (Lopez-Beltran, A.; Cheng, L.; Gevaert, T.; Blanca, A.; Cimadamore, A.; Santoni, M.; Massari, F.; Scarpelli, M.; Raspollini, M. R.; Montironi, R., Current and emerging bladder cancer biomarkers with an emphasis on urine biomarkers. EXPERT REVIEW OF MOLECULAR DIAGNOSTICS 2020, 20 (2), 231-243; Stephan, C.; Ralla, B.; Jung, K., Prostate-specific antigen and other serum and urine markers in prostate cancer. BIOCHIMICA ET BIOPHYSICA ACTA-REVIEWS ON CANCER 2014, 1846 (1), 99-112; and Wasung, M. E.; Chawla, L. S.; Madero, M., Biomarkers of renal function, which and when? CLINICA CHIMICA ACTA 2015, 438, 350-357). The most popular biomarker type for this diagnostic method are peptides, with many reports showing good diagnostic correlation of biomarker peptide libraries with kidney diseases such as lupus, kidney injury, and bladder cancer (Frantzi, M.; van Kessel, K. E.; Zwarthoff, E. C.; Marquez, M.; Rava, M.; Malats, N.; Merseburger, A. S.; Katafigiotis, I.; Stravodimos, K.; Mullen, W.; Zoidakis, J.; Makridakis, M.; Pejchinovski, M.; Critselis, E.; Lichtinghagen, R.; Brand, K.; Dakna, M.; Roubelakis, M. G.; Theodorescu, D.; Vlahou, A.; Mischak, H.; Anagnou, N. P., Development and Validation of Urine-based Peptide Biomarker Panels for Detecting Bladder Cancer in a Multi-center Study. CLINICAL CANCER RESEARCH 2016, 22 (16), 4077-4086; Aragon, C. C.; Tafur, R. A.; Suarez-Avellaneda, A.; Martinez, M. T.; de las Salas, A.; Tobon, G. J., Urinary biomarkers in lupus nephritis. JOURNAL OF TRANSLATIONAL AUTOIMMUNITY 2020, 3; and Klein, J.; Bascands, J. L.; Mischak, H.; Schanstra, J. P., The role of urinary peptidomics in kidney disease research. KIDNEY INTERNATIONAL 2016, 89 (3), 539-545). Proinflammatory chemokines (C—X—C and C—C motifs) are higher weight peptides (9-11 kda) that are highly representative examples of these urinary biomarkers for these diseases (Rovin, B. H.; Song, H. J.; Birmingham, D. J.; Hebert, L. A.; Yu, C. Y.; Nagaraja, H. N., Urine chemokines as biomarkers of human systemic lupus erythematosus activity. JOURNAL OF THE AMERICAN SOCIETY OF NEPHROLOGY 2005, 16 (2), 467-473; Jakiela, B.; Kosalka, J.; Plutecka, H.; Wegrzyn, A. S.; Bazan-Socha, S.; Sanak, M.; Musial, J., Urinary cytokines and mRNA expression as biomarkers of disease activity in lupus nephritis. LUPUS 2018, 27 (8), 1259-1270; and Shadpour, P.; Zamani, M.; Aghaalikhani, N.; Rashtchizadeh, N., Inflammatory cytokines in bladder cancer. JOURNAL OF CELLULAR PHYSIOLOGY 2019, 234 (9), 14489-14499). The differences in kinetic versus steady-state binding signal serve to shed light on the pulldown efficiency of the ionic polymers. Polymers for the microarray were selected for an emphasis on the expected preferential binding of the positively charged chemokines. At physiological pH CXCL8 is +5 and CXCL10 is +10, so negatively charged polymers PAA (mildly negative) and PSS (highly negative) were selected, with the positively charged PLL used as a comparison. PAH was not usable in imaging mode, as the initial reflectivity curves for its channel were significantly shifted to higher angles compared to the other polymers, while PLL was a much closer match (see FIG. 11(b)). This match is vital for the imaging mode, as the fixed angle is constant for each channel, and the relative intensity must be initially approximately equal to have comparable results across the array. The shift in the initial reflectivity curves from the polymers indicated high surface sensitivity, so as a test to ensure differential bulk sensitivity between channels was not a colluding factor in the binding analysis, solutions of NaCl were incubated over the microarray. The bulk shifts are shown in FIG. 12(b), and show consistent response across channels, thus this potential factor is minimal here.

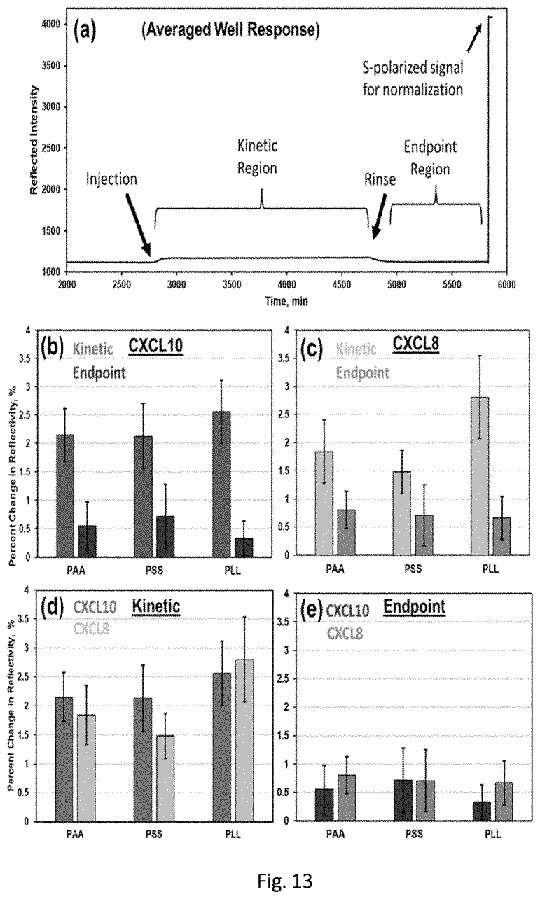

A full SPR imaging sensorgram (showing average of well intensities) of incubation of 20 μg/mL of the biomarkers is shown in FIG. 13(a), and comparisons of channel responses are given in FIG. 13, (b)-(e). The “endpoint”, or irreversible, binding signal in each case was relatively small, reflecting the low-intensity nature of the charge-based interactions. The clearest representation of charge effects can be seen in the comparison of the kinetic shifts between the two chemokines across the three channels (FIG. 13, (d)). For the negatively charged PAA and PSS polymer, there is a stronger association between the CXCL10 and the surface than for CXCL8. However, for the positively charged PLL, the kinetic data is reversed, with CXCL8 showing stronger affinity than CXCL10. This reflects the relative charge interactions for CXCL8 (+5) and CXCL10 (+10) at biological buffer pH (7.4). The more positively charged CXCL10 has higher association with the negatively charged surfaces but is consequently more repelled by the positively charged surface.

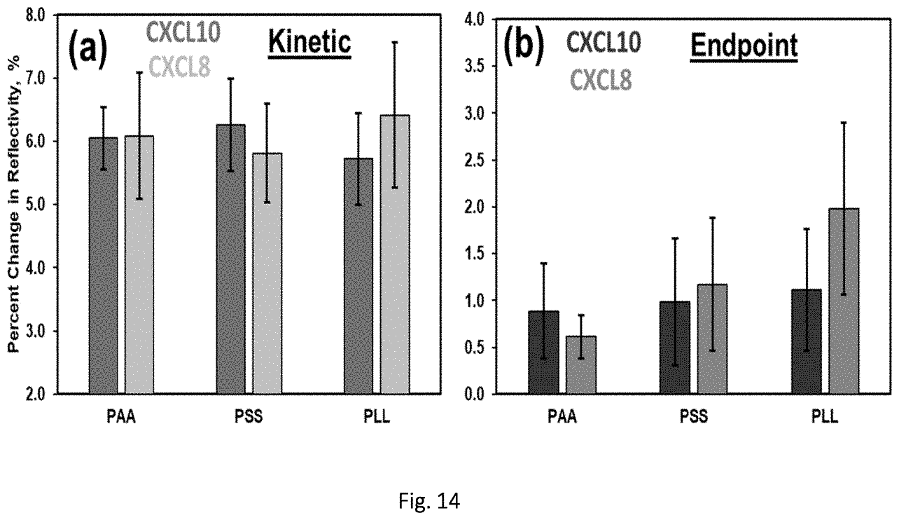

The effect of a complex biological matrix on this binding was investigated by spiking the chemokines into an artificial urine matrix, a popular medium for studying urine-based biomarkers such as chemokines for kidney and bladder disease (Shafat, M.; Rajakumar, K.; Syme, H.; Buchholz, N.; Knight, M. M., Stent encrustation in feline and human artificial urine: does the low molecular weight composition account for the difference? UROLITHIASIS 2013, 41 (6), 481-486; Mukanova, Z.; Gudun, K.; Elemessova, Z.; Khamkhash, L.; Ralchenko, E.; Bukasov, R., Detection of Paracetamol in Water and Urea in Artificial Urine with Gold Nanoparticle@Al Foil Cost-efficient SERS Substrate. ANALYTICAL SCIENCES 2018, 34 (2), 183-187; Tian, L. M.; Morrissey, J. J.; Kattumenu, R.; Gandra, N.; Kharasch, E. D.; Singamaneni, S., Bioplasmonic Paper as a Platform for Detection of Kidney Cancer Biomarkers. ANALYTICAL CHEMISTRY 2012, 84 (22), 9928-9934; and Ikeda, M.; Yoshii, T.; Matsui, T.; Tanida, T.; Komatsu, H.; Hamachi, I., Montmorillonite-Supramolecular Hydrogel Hybrid for Fluorocolorimetric Sensing of Polyamines. J. Am. Chem. Soc. 2011, 133 (6), 1670-1673) The much higher ionic strength and, more importantly, lower pH (˜6.0) of the urine matrix compared to PBS buffer serve to significantly alter the kinetic and endpoint data relationships, as shown in FIG. 14. Though the bulk refractive index shifts have a higher baseline value due to the urine matrix, taken together, the relative kinetic shifts of the two chemokines reflect a more protonating environment for the binding. For the PLL surface, the relative difference in response between CXCL10 and CXCL8 (+0.68%) is larger than seen with PBS buffer (+0.25%), in line with the PLL surface being more positively-charged and more discriminating between positively-charged peptides. Likewise, the PSS relative difference for urine (−0.45%) is smaller than that of PBS (−0.65%), and the PAA response is essentially leveled for urine, reflecting the inverse effect, that the polymers are less negatively charged and thus less discriminating. It should be noted that while the change in pH does also affect the charge of the two peptides and affects CXCL8 (+5 in PBS to +7 in urine) more than CXCL10 (+10 to +11), they are still distinct enough in their charge states that they follow the same pattern as before. The SPR imaging array thus serves as an effective platform for illustrating these the pH effect, as the realtime data can be more useful and representative of the biophysical interactions than endpoint data.

### Charge-Based Effects on MALDI-MS Analysis.

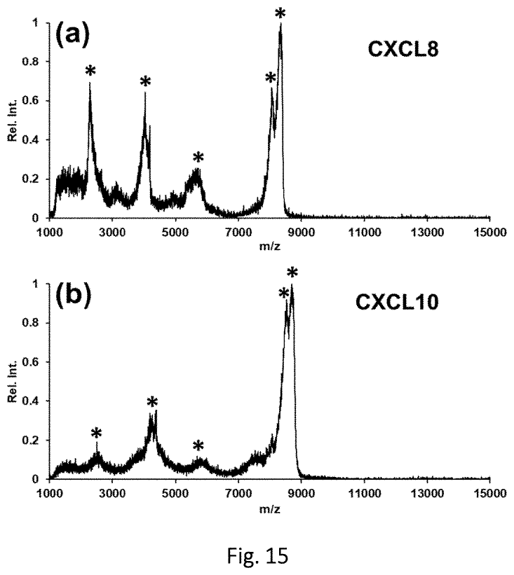

First, base spectra in linear positive mode were obtained on the Al₂O₃ surface, shown in FIG. 15. The intact peaks for both chemokines match the expected m/z values given the expressed constructs of each (CXCL8: A29-S99, 8299 kDa; CXCL10: V22-P98, 8646 kDa). The other primary peaks reflect both doubly-charged primary ions (CXCL8: 4100; CXCL10, 4350) and cleavages at the borders of the major subdomains of each, as the chemokines, while not sharing high sequence similarity, are highly homologous, with an α-helix near the C-terminus, two internal β-sheets and third β-sheet that promotes dimerization (Swaminathan, G. J.; Holloway, D. E.; Colvin, R. A.; Campanella, G. K.; Papageorgiou, A. C.; Luster, A. D.; Acharya, K. R., Crystal structures of oligomeric forms of the IP-10/CXCL10 chemokine. STRUCTURE 2003, 11 (5), 521-532; and Baldwin, E. T.; Weber, I. T.; Stcharles, R.; Xuan, J. C.; Appella, E.; Yamada, M.; Matsushima, K.; Edwards, B. F. P.; Clore, G. M.; Gronenborn, A. M.; Wlodawer, A., CRYSTAL-STRUCTURE OF INTERLEUKIN-8—SYMBIOSIS OF NMR AND CRYSTALLOGRAPHY. PROCEEDINGS OF THE NATIONAL ACADEMY OF SCIENCES OF THE UNITED STATES OF AMERICA 1991, 88 (2), 502-506). In both cases, the signals formed a distinct and consistent profile for identification. Notably, spectra of the same biomarkers obtained a conventional steel plate and an Au plate of the same microarray configuration as used in previous work have m/z intensity values significantly lower than those of the aluminum plate. This supports the assertion that the plasmonic absorption of the aluminum of the UV laser (337 nm) of the MALDI enhances the MS signal.

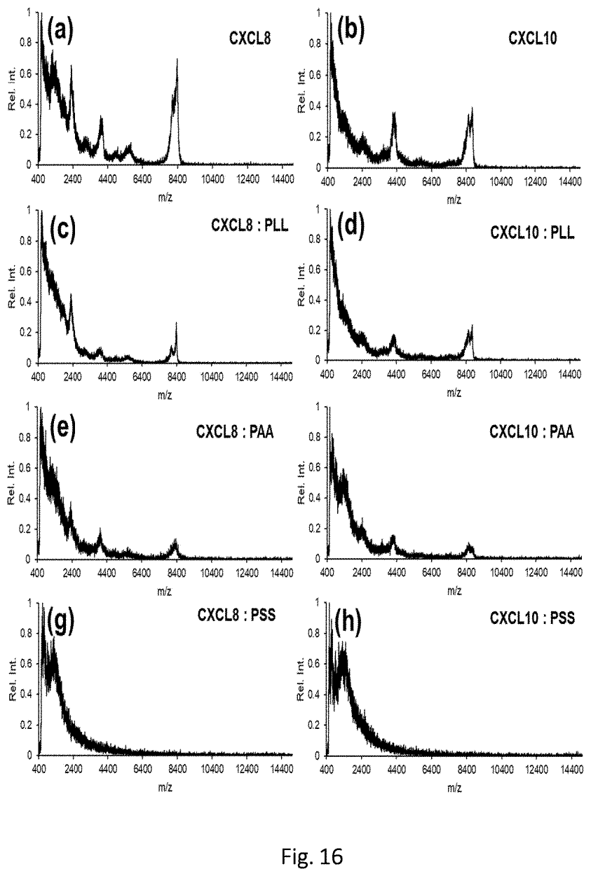

The MALDI-MS spectra in linear positive mode for the chemokines deposited directly onto the polymer surface are shown in FIG. 16. In all cases, the presence of polymer reduced signal, as would be expected from both the physical separation from the plasmonic surface and the dilution of charge transfer from the MALDI matrix. However, the trend across polymers revealed an unexpected charge-based effect. For both biomarkers, while the PLL coating resulted in a similar peak profile to the bare Al, the PAA coating generated much lower and broader signal intensities on the key identifying peak regions of m/z=2300, 4100, and 8350 for CXCL8 and m/z=4350 and 8700 for CXCL10. The PSS coating essentially suppressed all peaks, and as the peak intensities and sharpness decreased with increasingly negative polymer charge, this indicates that the negative polymer charge significantly affects ionization and signal of positive ions.

In total, for both biomarkers, the presence of peaks is directly correlated to the charge of the surface, with higher negative charge interfering with MALDI ionization. This interference effect was further reinforced by the final SPR-MALDI coupling, wherein the polymer-coated microarray chip was incubated and quantified on the SPR imaging setup, removed and spotted with MALDI matrix, and used for MALDI-MS analysis. The only surface where a small amount of identifying mass signal for the chemokines was on the bare Al/Al₂O₃ control channel.

Chemical Functionalization for Bioanalysis Via Al₂O₃Silanization

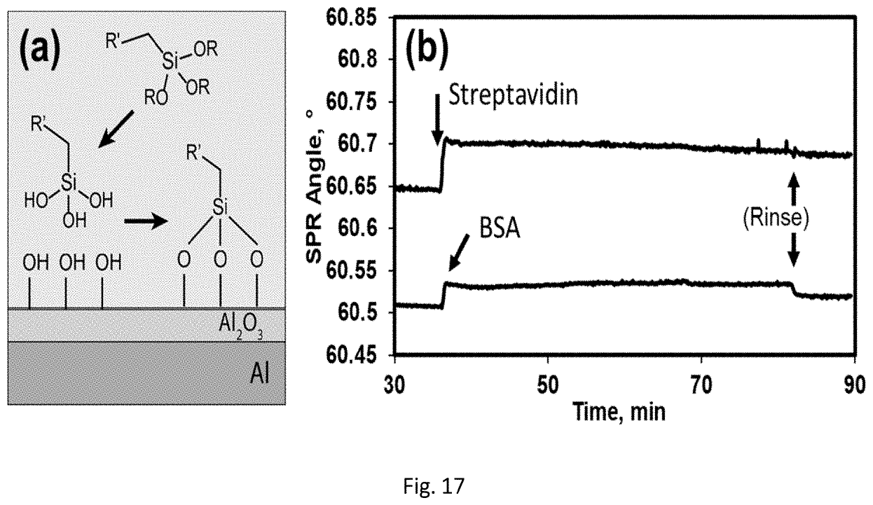

As a final direction, the functionalization of Al₂O₃ by chemical means (rather than physical) is a core component of the use of Al films in SPR biosensing. Immobilization of biological targets takes place via a variety of coupling chemistries, such as EDC/NHS or Ni:NTA-DGS (Vashist, S. K., Comparison of 1-Ethyl-3-(3-Dimethylaminopropyl) Carbodiimide Based Strategies to Crosslink Antibodies on Amine-Functionalized Platforms for Immunodiagnostic Applications. Disgnostics 2012, 2 (3), 23-33; and Bally, M.; Bailey, K.; Sugihara, K.; Grieshaber, D.; Voros, J.; Stadler, B., Liposome and Lipid Bilayer Arrays Towards Biosensing Applications. SMALL 2010, 6 (22), 2481-2497). However, the actual surface chemistry for Au and Ag films is essentially limited to thiol bonds. Here, we demonstrate a surface coupling chemistry for SPR biosensing that is not available for Au or Ag films: silanization. Biotin-PEG(2K)-silane was ligated to an Al thin film conventional SPR chip surface via the silane-oxygen bonds that catalyze into a self-assembled monolayer (see FIG. 17, (a)). The final chip was mounted on the conventional SPR and used to sense bacterial protein streptavidin via the strong biotin-streptavidin affinity. As shown in FIG. 17, (b), an incubation of 100 μg/mL of streptavidin generated a binding signal that remained even after rinsing, as compared to a control incubation of bovine serum albumin, which rinsed off. Thus, a new surface chemistry for conventional SPR biosensing Al₂O₃ silanization, was demonstrated for the first time.

### CONCLUSION

In summary, the applications of plasmonic aluminum films were investigated via conventional SPR, SPR imaging, and MALDI-MS as the building blocks for a wider range of analytical platforms. First, the bare Al film was shown to be effective at enrichment of phosphorylated peptides from milk proteins for mass spectrometric profiling. Second, Al films physically modified with ionic polymers were used with SPR and MALDI to analyze charge-based binding interactions for both large macromolecules (lipid vesicles) and highly medically relevant biomarkers. The qualitative separation of charged lipid vesicles by ionic polymers could be easily monitored and showed selectivity over the bare Al surface. In SPR imaging mode, the high sensitivity of aluminum allowed for quantification of kinetic differences of charge-based binding interactions between ionic polymers and biomarker peptides CXCL8 and CXCL10. The binding effects were clearly correlated to the charge densities of the biomarkers and the charged polymers, and the use of artificial urine matrix altered the association behavior in a well-defined manner. While the MALDI-MS ionization potential of the biomarkers was clearly affected by the polymer surface, the overall insights gleaned point towards a robust method of plasmonic screening of binding affinity by aluminum-based arrays. Finally, the functionalization of the Al₂O₃ overlayer by silanization was reported for selective binding of bacterial protein streptavidin in conventional SPR, the first successful example of a chemical functionalization for SPR biosensing that did not use Au or Ag films. The use of Al films for plasmonic label-free bioanalytical techniques is a subject of great potential and high upside for the future of understanding the complexities of biophysical interactions.

### Example 3

### Novel Plasmonic Al Substrates to Enhance MALDI-MS Based Lipid Profiling

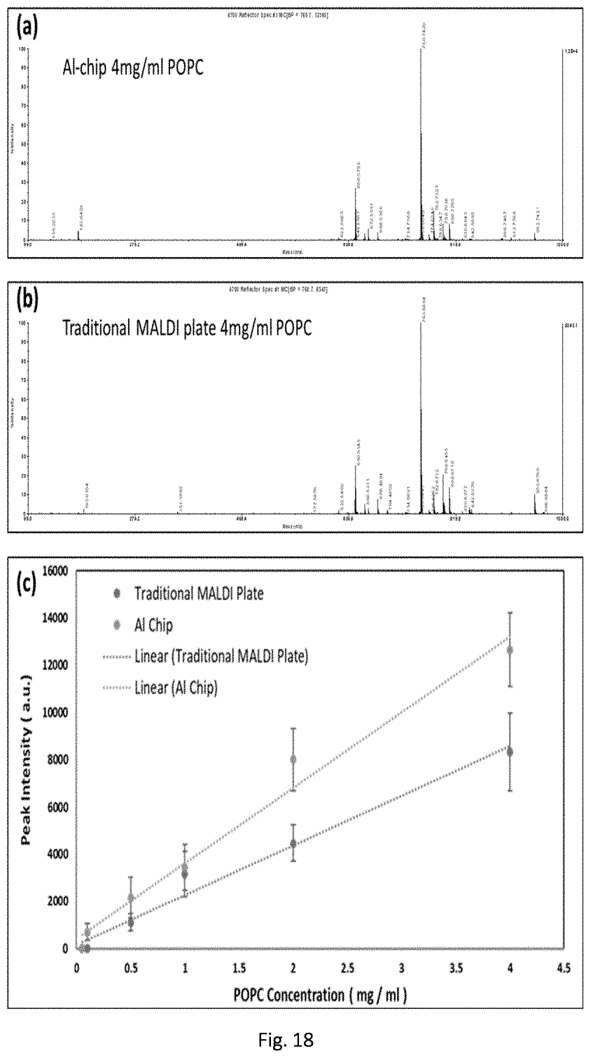

Additional research efforts have been focused on characterizing the Al thin film-based detection platform by SPR and MALDI. Various lipid molecules have been tested for improved signaling performance on the Al substrates by MALDI. We have observed better sensitivity with the Al films (FIG. 18), providing technical basis for expending the method (SPR-MALDI) to complex lipidomics studies (Note that the y-axis scale for FIG. 18, (a) is 1.2×10⁴ a.u., while that for FIG. 18, (b) is 8343 a.u.). The work further verified that plasmonic absorption of the aluminum of the UV laser (337 nm) used in the MALDI-MS experiments enhances the MS signals.

While the present description sets forth specific details of various embodiments, it will be appreciated that the description is illustrative only and should not be construed in any way as limiting. Furthermore, various applications of such embodiments and modifications thereto, which may occur to those who are skilled in the art, are also encompassed by the general concepts described herein. Each and every feature described herein, and each and every combination of two or more of such features, is included within the scope of the present invention provided that the features included in such a combination are not mutually inconsistent.

All figures, tables, and appendices, as well as patents, applications, and publications, referred to above, are hereby incorporated by reference in their entireties.

Some embodiments have been described in connection with the accompanying drawing. However, it should be understood that the figures are not drawn to scale. Distances, angles, etc. are merely illustrative and do not necessarily bear an exact relationship to actual dimensions and layout of the devices illustrated. Components can be added, removed, and/or rearranged. Further, the disclosure herein of any particular feature, aspect, method, property, characteristic, quality, attribute, element, or the like in connection with various embodiments can be used in all other embodiments set forth herein. Additionally, it will be recognized that any methods described herein may be practiced using any device suitable for performing the recited steps.

For purposes of this disclosure, certain aspects, advantages, and novel features are described herein. It is to be understood that not necessarily all such advantages may be achieved in accordance with any particular embodiment. Thus, for example, those skilled in the art will recognize that the disclosure may be embodied or carried out in a manner that achieves one advantage or a group of advantages as taught herein without necessarily achieving other advantages as may be taught or suggested herein.

Although these inventions have been disclosed in the context of certain preferred embodiments and examples, it will be understood by those skilled in the art that the present inventions extend beyond the specifically disclosed embodiments to other alternative embodiments and/or uses of the inventions and obvious modifications and equivalents thereof. In addition, while several variations of the inventions have been shown and described in detail, other modifications, which are within the scope of these inventions, will be readily apparent to those of skill in the art based upon this disclosure. It is also contemplated that various combination or sub-combinations of the specific features and aspects of the embodiments may be made and still fall within the scope of the inventions. It should be understood that various features and aspects of the disclosed embodiments can be combined with or substituted for one another in order to form varying modes of the disclosed inventions. Further, the actions of the disclosed processes and methods may be modified in any manner, including by reordering actions and/or inserting additional actions and/or deleting actions. Thus, it is intended that the scope of at least some of the present inventions herein disclosed should not be limited by the particular disclosed embodiments described above. The limitations in the claims are to be interpreted broadly based on the language employed in the claims and not limited to the examples described in the present specification or during the prosecution of the application, which examples are to be construed as non-exclusive.

Unless otherwise indicated, all numbers expressing quantities of ingredients, properties such as molecular weight, reaction conditions, and so forth used in the specification and claims are to be understood as being modified in all instances by the term “about.” As used herein, the term “about” means that the item, parameter or term so qualified encompasses a range of plus or minus ten percent above and below the value of the stated item, parameter or term. Accordingly, unless indicated to the contrary, the numerical parameters set forth in the specification and attached claims are approximations that may vary depending upon the desired properties sought to be obtained by the present invention. At the very least, and not as an attempt to limit the application of the doctrine of equivalents to the scope of the claims, each numerical parameter should at least be construed considering the number of reported significant digits and by applying ordinary rounding techniques. Notwithstanding that the numerical ranges and parameters setting forth the broad scope of the invention are approximations, the numerical values set forth in the specific examples are reported as precisely as possible. Any numerical value, however, inherently contains certain errors necessarily resulting from the standard deviation found in their respective testing measurements.

The terms “a,” “an,” “the” and similar referents used in the context of describing the invention (especially in the context of the following claims) are to be construed to cover both the singular and the plural, unless otherwise indicated herein or clearly contradicted by context. Recitation of ranges of values herein is merely intended to serve as a shorthand method of referring individually to each separate value falling within the range. Unless otherwise indicated herein, each individual value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein is intended merely to better illuminate the invention and does not pose a limitation on the scope of the invention otherwise claimed. No language in the specification should be construed as indicating any non-claimed element essential to the practice of the embodiments disclosed in the present disclosure.

Groupings of alternative elements or embodiments of the invention disclosed herein are not to be construed as limitations. Each group member may be referred to and claimed individually or in any combination with other members of the group or other elements found herein. It is anticipated that one or more members of a group may be included in, or deleted from, a group for reasons of convenience and/or patentability. When any such inclusion or deletion occurs, the specification is deemed to contain the group as modified thus fulfilling the written description of all Markush groups used in the appended claims.

It is contemplated that various combinations or sub-combinations of the specific features and aspects of the embodiments disclosed above may be made and still fall within one or more of the inventions. Further, the disclosure herein of any particular feature, aspect, method, property, characteristic, quality, attribute, element, or the like in connection with an embodiment can be used in all other embodiments set forth herein. Accordingly, it should be understood that various features and aspects of the disclosed embodiments can be combined with or substituted for one another in order to form varying modes of the disclosed inventions. Thus, it is intended that the scope of the present inventions herein disclosed should not be limited by the particular disclosed embodiments described above. Moreover, while the invention is susceptible to various modifications, and alternative forms, specific examples thereof have been shown in the drawings and are herein described in detail. It should be understood, however, that the invention is not to be limited to the particular forms or methods disclosed, but to the contrary, the invention is to cover all modifications, equivalents, and alternatives falling within the spirit and scope of the various embodiments described and the appended claims. Any methods disclosed herein need not be performed in the order recited. The methods disclosed herein include certain actions taken by a practitioner; however, they can also include any third-party instruction of those actions, either expressly or by implication. In addition, where features or aspects of the disclosure are described in terms of Markush groups, those skilled in the art will recognize that the disclosure is also thereby described in terms of any individual member or subgroup of members of the Markush group.

The ranges disclosed herein also encompass any and all overlap, sub-ranges, and combinations thereof. Language such as “up to,” “at least,” “greater than,” “less than,” “between,” and the like includes the number recited. Numbers preceded by a term such as “about” or “approximately” include the recited numbers. For example, “about 90%” includes “90%.” In some embodiments, at least 95% includes 96%, 97%, 98%, 99%, and 100% as compared to a reference.

Any titles or subheadings used herein are for organization purposes and should not be used to limit the scope of embodiments disclosed herein.

What is claimed is:

1. A thin aluminum film substrate for surface plasmon resonance analysis comprising:
a substrate, and
a thin film of aluminum deposited on the substrate.

2. The thin aluminum film substrate of claim 1, wherein the substrate comprises a material selected from the group consisting of silicate glass, borosilicate glass, quartz, sapphire, polymerized polylactic acid, and polymerized poly(methyl methacrylate).

3. The thin aluminum film substrate of claim 1, wherein the thin film of aluminum comprises aluminum metal and an oxidized layer of Al₂O₃ on the aluminum metal.

4. The thin aluminum film substrate of claim 3, wherein a ratio of the Al/Al₂O₃ is about 4:1.

5. The thin aluminum film substrate of claim 3, wherein a thickness of the Al is between 10-200 nm and a thickness of the Al₂O₃ is about 1-20 nm.

6. The thin aluminum film substrate of claim 3, wherein a thickness of the Al is about 12 nm and a thickness of the Al₂O₃ is about 3 nm.

7. The thin aluminum film substrate of claim 1, wherein the thin metal film is attached to an attenuated total reflection (ATR) optical coupler.

8. The thin aluminum film substrate according to claim 3, wherein the layer of Al₂O₃ is functionalized to enable immobilization of a biomolecule.

9. The thin aluminum film substrate according to claim 3, wherein the layer of Al₂O₃ is functionalized by silanization, carboxylation or phosphonylation.

10. The thin aluminum film substrate according to claim 8, wherein the functionalized layer of Al₂O₃ is bound to biotin.

11. A microarray with a plurality of wells comprising the thin aluminum film substrate according claim 1 deposited at the bottoms of the wells, wherein wells are surrounded by a layer of aluminum deposited on the substrate that is thicker compared to the layer of aluminum deposited at bottoms of the wells.

12. The microarray according to claim 11, wherein the wells are 100-300 nm deep and 400-800 μm in diameter.

13. A method of forming the thin aluminum film substrate for surface plasmon resonance analysis according to claim 1, the method comprising:
providing a substrate,
using electron-beam physical vapor deposition (EBPVD) to deposit a thin film of Al on a surface of the substrate.

14. The method of claim 13, further comprising allowing the thin film of aluminum to oxidize so that the thin aluminum film comprises a layer of Al₂O₃.

15. A method of forming the microarray according to claim 11 comprising:
providing a substrate,
applying a photoresist to the substrate,
applying well spots of photomask to the photoresist to define areas that will become wells in the microarray,
depositing aluminum by EBPVD onto the masked substrate, wherein a thin layer of aluminum is deposited onto areas not blocked by the photomask,
removing the well spots of photomask, and
depositing aluminum by EBPVD onto the microarray to build up walls around the wells and to coat the bottoms of the wells that are no longer masked.

16. A method of detecting an analyte comprising:
providing the thin aluminum film substrate according to claim 1, wherein a functionalized surface of the thin aluminum film comprises a biomolecule,
applying a sample comprising the analyte to the thin aluminum film substrate, and
using surface plasmon resonance (SPR) spectroscopy to detect molecular interactions between the biomolecule and the analyte at a surface of the thin aluminum film substrate.

17. The method of claim 16, further comprising allowing the thin film of aluminum to oxidize so that the thin aluminum film comprises a layer of Al₂O₃.

18. The method according to claim 16, wherein a sensor biomolecule is attached to a functionalized surface of the thin aluminum film is biotin and the analyte in the sample is conjugated to streptavidin.

19. The method of claim 16, wherein the sample comprising the analyte is a blood or serum sample, and wherein the Al/Al₂O₃ layer suppresses nonspecific binding from proteins and lipids in the blood or serum sample.

20. The method according to claim 16, wherein the SPR spectroscopy comprises SPR imaging.

21. A method of enriching phosphorylated peptides on an aluminum array in SPR biosensing, SPR imaging or MALDI-MS analysis comprising using the thin aluminum film substrate according to claim 3, which comprises aluminum metal and an oxidized layer of Al₂O₃ on the aluminum metal.

22. The thin aluminum film substrate according to claim 1, further comprising a coating of an ionic polymer.

23. The thin aluminum film substrate according to claim 22, wherein the ionic polymer is selected from the group consisting of 1-Palmitoyl-2-oleoyl-glycero-3-phosphocholine (POPC), 1,2-dioleoyl-sn-glycero-3-ethylphosphocholine (EPC), and 1-palmitoyl-2-oleoyl-sn-glycero-3-phospho-(1′-rac-glycerol) (POPG).

24. A method of analyzing charged-based interactions of biomolecules comprising using the thin aluminum film substrate according to claim 22.


SEQUENCE LISTING (3 sequences)

SEQ ID NO: 1 - protein, 16 aa, Artificial Sequence
  peptide
DIGSESTEDQAMEDIK

SEQ ID NO: 2 - protein, 20 aa, Artificial Sequence
  peptide
NTMEHVSSSEESIISQETYK

SEQ ID NO: 3 - protein, 25 aa, Artificial Sequence
  peptide
RELEELNVPGEIVESLSSSEESITR